(19) United States
(12) Patent Application Publication
(10) Pub. No.: US 2024/0371889 A1
(43) Pub. Date: Nov. 7, 2024

(54) DISPLAY DEVICE AND TILED DISPLAY DEVICE

(71) Applicant: Samsung Display Co., LTD., Yongin-si (KR)

(72) Inventor: Sang Hyung LIM, Yongin-si (KR)

(73) Assignee: Samsung Display Co., LTD., Yongin-si (KR)

(21) Appl. No.: 18/591,298

(22) Filed: Feb. 29, 2024

(30) Foreign Application Priority Data
May 4, 2023 (KR) 10-2023-0058512

(51) Int. Cl. H01L 27/12; H01L 25/16

(52) U.S. Cl. CPC H01L 27/124; H01L 25/167; H01L 27/1259; H01L 27/1218

(57) ABSTRACT

A display device includes a substrate having a lower surface on which a groove is formed, a conductive pattern disposed in the groove of the substrate, a bridge pattern disposed on the substrate and electrically connected to the conductive pattern through a contact hole passing through the substrate, a first insulating layer disposed on the substrate and covering the bridge pattern, a transistor disposed on the first insulating layer, a second insulating layer disposed on the substrate and covering the transistor, and a light emitting element disposed on the second insulating layer. The bridge pattern is electrically connected to the transistor or the light emitting element. A first valley is further formed on the lower surface of the substrate, the first valley and the groove being different from each other, and a conductive pattern is not disposed in the first valley.

### CROSS REFERENCE TO RELATED APPLICATION(S)

This application claims priority to and benefits of Korean Patent Application No. 10-2023-0058512 under 35 U.S.C. § 119, filed on May 4, 2023, in the Korean Intellectual Property Office (KIPO), the entire contents of which are incorporated herein by reference.

### BACKGROUND

### 1. Technical Field

Embodiments relate to a display device and a tiled display device.

### 2. Description of the Related Art

A tiled display device may be implemented by stitching multiple display panels, and in case that a dead space exists in each display panel, a boundary between the display panels may be visually recognized, and display quality of an image displayed on the tiled display device may be deteriorated.

Therefore, in order to reduce the dead space of the display panel, a pad is formed on a rear surface of the display panel.

A pad on a rear surface of a display panel is electrically connected to a circuit inside a display panel through a connection line (or a side line) formed on a side surfaces of the display panel.

For example, a rear surface process for forming the pad on the rear surface of the display panel and a side surface process for forming the connection line on the side surface of the display panel are added, a manufacturing process of a display device becomes complex. In case that a connection line on the side surface of the display panel is exposed, reliability of the display panel may be deteriorated.

### SUMMARY

The disclosure provides a display device and a tiled display device that may be manufactured by a simpler process and having high reliability.

According to embodiments of the disclosure, a display device may include a substrate including a groove on a lower surface, a conductive pattern disposed in the groove of the substrate, a bridge pattern disposed on the substrate and electrically connected to the conductive pattern through a contact hole passing through the substrate, a first insulating layer disposed on the substrate and covering the bridge pattern, a transistor disposed on the first insulating layer, a second insulating layer disposed on the substrate and covering the transistor, and a light emitting element disposed on the second insulating layer. The bridge pattern may be electrically connected to the transistor or the light emitting element, a first valley different from the groove may be further formed on the lower surface of the substrate, and the conductive pattern may be not disposed in the first valley.

The substrate may be a flexible substrate.

In a cross-sectional view, a shape of the first valley and a shape of the groove may be different from each other.

In a cross-sectional view, the groove may have a semicircular shape, and the first valley may have a triangular shape.

In a plan view, the first valley may extend in a first direction and may be repeatedly arranged in a second direction intersecting the first direction with an interval corresponding to the light emitting element.

In a plan view, the first valley may be arranged in a mesh structure over an entire area of the substrate.

The display device may further include a pixel defining layer disposed on the second insulating layer. An opening for disposing the light emitting element and a second valley different from the opening may be formed in the pixel defining layer, and the first valley may overlap the second valley in a plan view.

The display device may further include a circuit board disposed under the substrate and electrically connected to the conductive pattern through the groove of the substrate.

The groove may include a curved surface, and the conductive pattern may include a curved surface corresponding to the groove.

At least a portion of the groove may be defined by a lower surface of the conductive pattern.

The light emitting element may be included in multiple sub-pixels, and the groove may be repeatedly arranged with an interval corresponding to at least one of the sub-pixels in a first direction.

The groove may have a size corresponding to the sub-pixels, and multiple conductive patterns may be disposed in the groove.

According to embodiments of the disclosure, a method of manufacturing a display device may include forming a first mold pattern on a carrier substrate, forming a conductive pattern on the first mold pattern, forming a base layer on the carrier substrate to cover the first mold pattern and the conductive pattern, forming a transistor on the base layer, separating the carrier substrate and the first mold pattern from the base layer, and mounting a light emitting element on the base layer. A groove corresponding to the first mold pattern may be formed on a lower surface of the base layer.

The forming of the first mold pattern may include forming a sacrificial layer on the carrier substrate, and stamping the sacrificial layer using a mold including a second groove corresponding to the first mold pattern. The sacrificial layer may include silica sol-gel (Si sol-gel) or a polymeric organic material.

The forming of the first mold pattern may further include forming a second mold pattern together with the first mold pattern. In a cross-sectional view, a shape of the second mold pattern and a shape of the first mold pattern may be different from each other, and a first valley corresponding to the second mold pattern may be formed on a lower surface of the base layer.

The forming of the transistor may include forming a pixel defining layer on the base layer. An opening for disposing the light emitting element and a second valley different from the opening may be formed in the pixel defining layer, and the first valley may overlap the second valley in a plan view.

According to embodiments of the disclosure, a tiled display device may include multiple display devices each including pixels. The display devices may be disposed adjacent to each other by an interval corresponding to an interval between the pixels. At least one of the display devices may include a substrate including a groove on a lower surface, a conductive pattern disposed in the groove of the substrate, a bridge pattern disposed on the substrate and electrically connected to the conductive pattern through a contact hole passing through the substrate, a first insulating layer disposed on the substrate and covering the bridge pattern, a transistor disposed on the first insulating layer, a second insulating layer disposed on the substrate and covering the transistor, and a light emitting element disposed on the second insulating layer. The bridge pattern may be electrically connected to the transistor or the light emitting element. A first valley different from the groove may be further formed on the lower surface of the substrate.

At least some of the display devices may have different sizes or different shapes.

At least some of the display devices may have different resolutions.

The substrate may be a flexible substrate.

In the display device according to embodiments of the disclosure, the transistor or the light emitting element may be electrically connected to the circuit board through the conductive pattern in the groove formed on the lower surface of the substrate and the contact hole passing through the substrate. Accordingly, a connection line may be not disposed on a side surface of the display device, reliability deterioration due to the connection line may be prevented, and a dead space of the display device may be reduced or eliminated.

The method of manufacturing the display device according to embodiments of the disclosure may manufacture the display device only through a front surface process of sequentially forming the conductive pattern, the base layer, the transistor, and the like on the carrier substrate. Accordingly, a rear surface process for forming a conductive pattern under the base layer or a side surface process for forming a connection line on a side surface of the display device may be excluded, and a display device without a dead space may be manufactured through a simpler process.

An effect according to embodiments of the disclosure is not limited by a content described above as an example, and more various effects are included in the specification.

### BRIEF DESCRIPTION OF THE DRAWINGS

The above and other features of the disclosure will become more apparent by describing in further detail embodiments thereof with reference to the accompanying drawings, in which:

FIG. 1 is a schematic plan view illustrating a display device according to an embodiment;

FIG. 2 is a schematic diagram illustrating a pixel of FIG. 1 according to an embodiment;

FIG. 3 is a schematic diagram illustrating a pixel of FIG. 1 according to another embodiment;

FIG. 4 is a schematic diagram of an equivalent circuit illustrating a sub-pixel included in the pixel of FIGS. 2 and 3 according to an embodiment;

FIG. 5 is a schematic plan view illustrating the display device of FIG. 1 according to an embodiment;

FIG. 6 is a schematic diagram illustrating a connection relationship between a pixel circuit and a stage included in the display device of FIG. 5;

FIG. 7 is a schematic cross-sectional view illustrating the display device of FIG. 1 according to an embodiment;

FIGS. 8 and 9 are schematic bottom views of the display device illustrating a groove included in the display device of FIG. 7;

FIGS. 10 and 11 are schematic cross-sectional views illustrating a method of manufacturing the display device of FIG. 7;

FIG. 12 is a schematic cross-sectional view illustrating the display device of FIG. 1 according to an embodiment;

FIG. 13 is a schematic cross-sectional view illustrating a method of manufacturing the display device of FIG. 12;

FIG. 14 is a schematic plan view illustrating the display device of FIG. 12 according to an embodiment;

FIG. 15 is a schematic diagram illustrating the display device of FIG. 1 according to an embodiment;

FIG. 16 is a schematic cross-sectional view illustrating the display device of FIG. 1 according to an embodiment;

FIG. 17 is a schematic bottom view of a display device illustrating a valley included in the display device of FIG. 16;

FIGS. 18 and 19 are schematic cross-sectional views illustrating a method of manufacturing the display device of FIG. 16;

FIGS. 20 and 21 are schematic cross-sectional views illustrating the display device of FIG. 1 according to an embodiment;

FIG. 22 is a schematic bottom view of the display device illustrating a groove included in the display device of FIGS. 20 and 21;

FIG. 23 is a schematic plan view illustrating a tiled display device including multiple display devices according to an embodiment;

FIG. 24 is a schematic enlarged plan view of area AA of FIG. 23; and

FIG. 25 is a schematic block diagram illustrating a tiled display device according to an embodiment.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

The advantages and features of the disclosure and a method of achieving them will become apparent with reference to the embodiments described in detail below together with the accompanying drawings. However, the disclosure is not limited to the embodiments disclosed below, and may be implemented in various different forms. The embodiments are provided so that the disclosure will be thorough and complete and those skilled in the art to which the disclosure pertains can fully understand the scope of the disclosure. The disclosure is only defined by the scope of the claims.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” “including,” “has,” and/or “having,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

A case in which an element or a layer is referred to as “on” another element or layer includes a case in which another layer or another element is disposed directly on the other element or between the other layers. When, however, an element or layer is referred to as being “directly on” another element or layer, there are no intervening elements or layers present. The same reference numerals denote to the same components throughout the specification. A shape, a size, a ratio, an angle, the number, and the like disclosed in the drawings for describing the embodiments are exemplary, and thus, the disclosure is not limited thereto.

A term “connection” between two configurations may mean that both of an electrical connection and a physical connection are used inclusively, but is not limited thereto. For example, “connection” used based on a circuit diagram may mean an electrical connection, and “connection” used based on a cross-sectional view and a plan view may mean a physical connection.

When a component is described herein to “connect” another component to the other component or to be “connected to” other components, the components may be connected to each other as separate elements, or the components may be integral with each other. Also, throughout the specification, when an element is referred to as being “connected” to another element, the element may be “directly connected” to another element, or “electrically connected” to another element with one or more intervening elements interposed therebetween.

Although “first,” “second,” and the like are used to describe various components, these components are not limited by these terms. These terms are used only to distinguish one component from another component. Therefore, a first component mentioned below may be a second component within the technical spirit of the disclosure.

Each of features of various embodiments of the disclosure may be coupled or combined with each other in part or in whole, and technically various interlocking and driving are possible. Each embodiment may be implemented independently of each other and association thereof may be implemented together.

For the purposes of this disclosure, the phrase “at least one of A and B” may be construed as A only, B only, or any combination of A and B. “At least one of X, Y, and Z” and “at least one selected from the group consisting of X, Y, and Z” may be construed as X only, Y only, Z only, or any combination of two or more of X, Y, and Z. Also, “at least two of X, Y, and Z” may be construed as two or more of X, Y, and Z such as both X and Y, both X and Z, both Y and Z, both X, Y, and Z.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Spatially relative terms, such as “below,” “under,” “lower,” “above,” “upper,” “over,” “side,” and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the example term “below” can encompass both an orientation of above and below. Furthermore, the apparatus may be otherwise oriented (e.g., rotated 90 degrees or at other orientations), and, as such, the spatially relative descriptors used herein interpreted accordingly.

As customary in the field, some embodiments are described and illustrated in the accompanying drawings in terms of functional blocks, units, parts, and/or modules. Those skilled in the art will appreciate that these blocks, units, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, parts, and/or modules being implemented by microprocessors or other similar hardware, they may be programmed and controlled using software (e.g., microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (e.g., one or more programmed microprocessors and associated circuitry) to perform other functions. Also, each block, unit, part, and/or module of some example embodiments may be physically separated into two or more interacting and discrete blocks, units, parts, and/or modules without departing from the scope of the disclosure. Further, the blocks, units, parts, and/or modules of some example embodiments may be physically combined into more complex blocks, units, parts, and/or modules without departing from the scope of the disclosure.

Unless otherwise specified, the illustrated embodiments are to be understood as providing example features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

The first direction DR1, the second direction DR2, and the third direction DR3 are not limited to three axes of a rectangular coordinate system, such as the x, y, and z axes, and may be interpreted in a broader sense. For example, the first direction DR1, the second direction DR2, and the third direction DR3 may be perpendicular to one another, or may represent different directions that are not perpendicular to one another.

The display surface may be parallel to a surface defined by a first direction DR1 and a second direction DR2. A normal direction of the display surface, i.e., a thickness direction of the display device 10, may indicate a third direction DR3. In this specification, an expression of “when viewed from the top or in a plan view” may represent a case when viewed in the third direction DR3. Hereinafter, a front surface (or a top surface) and a rear surface (or a bottom surface) of each of layers or units may be distinguished by the third direction DR3. However, directions indicated by the first to third directions DR1, DR2, and DR3 may be a relative concept, and converted with respect to each other, e.g., converted into opposite directions.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments are described with reference to the accompanying drawings.

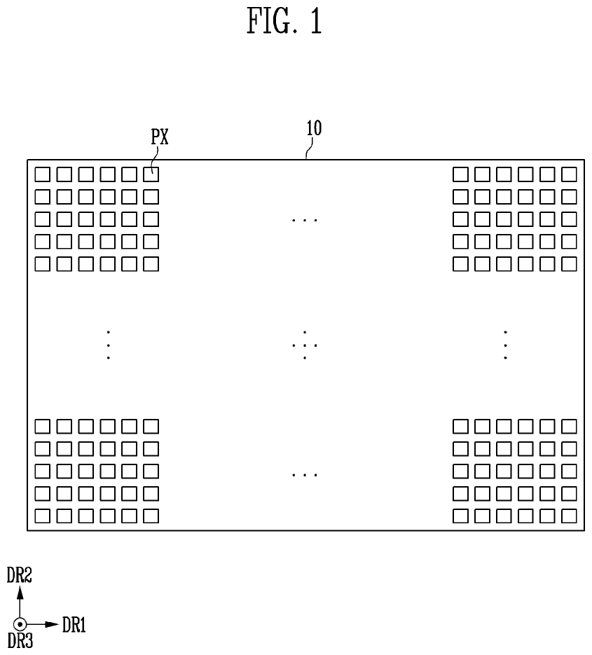

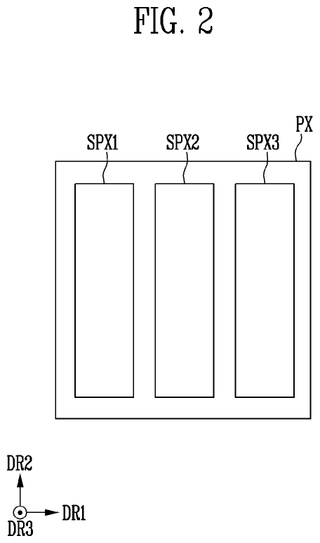

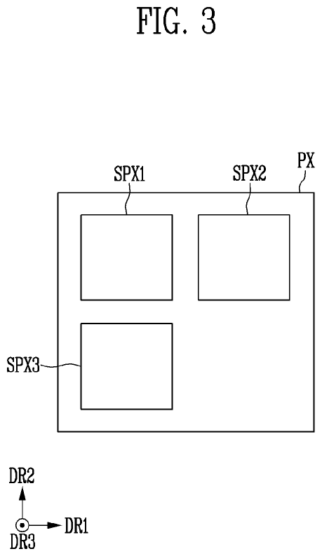

FIG. 1 is a schematic plan view illustrating a display device according to an embodiment. FIG. 2 is a schematic diagram illustrating a pixel of FIG. 1 according to an embodiment. FIG. 3 is a schematic diagram illustrating a pixel of FIG. 1 according to another embodiment.

Referring to FIG. 1, the display device 10 (or a display panel) may be a device displaying an image, and may be used as a display screen of various products such as not only a portable electronic device such as a mobile phone, a smart phone, a tablet personal computer (PC), a smart watch, a watch phone, a mobile communication terminal, an electronic notebook, an electronic book, a portable multimedia player (PMP), a navigation device, an ultra-mobile PC (UMPC), and the like, but also a television, a notebook computer, a monitor, a billboard, Internet of things (IOT), and the like.

The display device 10 may have a rectangular shape having a long side in a first direction DR1 and a short side in a second direction DR2 intersecting the first direction DR1 in a plan view. A corner where the long side of the first direction DR1 and the short side of the second direction DR2 meet may be rounded to have a curvature (e.g., a predetermined or selectable curvature) or have a right angle in a plan view. However, a shape of the display device 10 is not limited to a quadrangle, and in another embodiment, a shape of the display device 10 may another polygon, circle, ellipse, or the like in a plan view. The display device 10 may be flat, but the disclosure is not limited thereto. The display device 10 may have an atypical shape in a plan view. For example, the display device 10 may include a curved portion formed at left and right ends having a curvature (e.g., a constant or selectable curvature or a varying curvature). The display device 10 may be flexibly formed to be crooked, curved, bent, folded, or rolled.

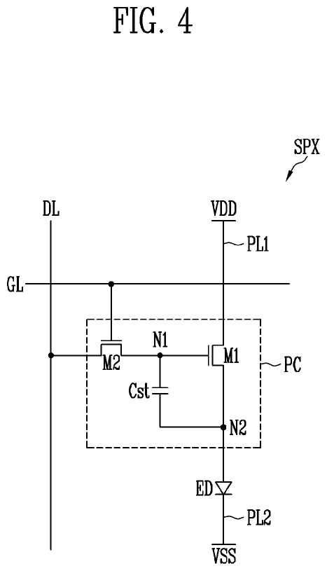

The display device 10 may include the pixels PX. The pixels PX may be arranged in a matrix form in the first direction DR1 and the second direction DR2, but the disclosure is not limited thereto. The display device 10 may further include gate lines (or scan lines) (see, e.g., GL of FIG. 4) extending in the first direction DR1 and data lines extending in the second direction DR2.

Each of the pixels PX may include sub-pixels SPX1, SPX2, and SPX3 as shown in FIGS. 2 and 3. FIGS. 2 and 3 illustrate that each of the pixels PX includes three sub-pixels SPX1 to SPX3, for example, a first sub-pixel SPX1, a second sub-pixel SPX2, and a third sub-pixel SPX3, but the disclosure is not limited thereto.

Each of the first sub-pixel SPX1, the second sub-pixel SPX2, and the third sub-pixel SPX3 may be electrically connected to one of the data lines (see, e.g., DL of FIG. 4) and at least one of the gate lines.

Referring to FIG. 2, each of the first sub-pixel SPX1, the second sub-pixel SPX2, and the third sub-pixel SPX3 may have a shape of a rectangle, a square, a rhombus, or the like in a plan view. For example, each of the first sub-pixel SPX1, the second sub-pixel SPX2, and the third sub-pixel SPX3 may have a shape of a rectangle having a short side in the first direction DR1 and a long side in the second direction DR2 as shown in FIG. 2 in a plan view. In another embodiment, each of the first sub-pixel SPX1, the second sub-pixel SPX2, and the third sub-pixel SPX3 may have a square or a rhombus including sides having a same length in the first direction DR1 and the second direction DR2 as shown in FIG. 3 in a plan view.

Referring to FIG. 2, the first sub-pixel SPX1, the second sub-pixel SPX2, and the third sub-pixel SPX3 may be arranged in the first direction DR1. In another embodiment, the first sub-pixel SPX1 and one of the second sub-pixel SPX2 and the third sub-pixel SPX3 may be arranged in the first direction DR1, and the first sub-pixel SPX1 and another one of the second sub-pixel SPX2 and the third sub-pixel SPX3 may be arranged in the second direction DR2. For example, referring to FIG. 3, the first sub-pixel SPX1 and the second sub-pixel SPX2 may be arranged in the first direction DR1, and the first sub-pixel SPX1 and the third sub-pixel SPX3 may be arranged in the second direction DR2.

In another embodiment, the second sub-pixel SPX2 and one of the first sub-pixel SPX1 and the third sub-pixel SPX3 may be arranged in the first direction DR1, and the second sub-pixel SPX2 and another one of the first sub-pixel SPX1 and the third sub-pixel SPX3 may be arranged in the second direction DR2. In another embodiment, the third sub-pixel SPX3 and one of the first sub-pixel SPX1 and the second sub-pixel SPX2 may be arranged in the first direction DR1, and the third sub-pixel SPX3 and another one of the first sub-pixel SPX1 and the second sub-pixel SPX2 may be arranged in the second direction DR2.

The first sub-pixel SPX1 may emit first light, the second sub-pixel SPX2 may emit second light, and the third sub-pixel SPX3 may emit third light. The first light may be light of a red wavelength band, the second light may be light of a green wavelength band, and the third light may be light of a blue wavelength band. The red wavelength band may be a wavelength band in a range of about 600 nm to about 750 nm, the green wavelength band may be a wavelength band in a range of about 480 nm to about 560 nm, and the blue wavelength band may be a wavelength band in a range of about 370 nm to about 460 nm, but the disclosure is not limited thereto.

Each of the first sub-pixel SPX1, the second sub-pixel SPX2, and the third sub-pixel SPX3 may include an inorganic light emitting element including an inorganic semiconductor as a light emitting element that emits light. For example, the inorganic light emitting element may be a flip chip type of micro light emitting diode (LED), but the disclosure is not limited thereto.

Referring to FIGS. 2 and 3, an area of the first sub-pixel SPX1, an area of the second sub-pixel SPX2, and an area of the third sub-pixel SPX3 may be substantially the same in a plan view, but the disclosure is not limited thereto. At least one of the area of the first sub-pixel SPX1, the area of the second sub-pixel SPX2, and the area of the third sub-pixel SPX3 and another one of the area of the first sub-pixel SPX1, the area of the second sub-pixel SPX2, and the area of the third sub-pixel SPX3 may be different. In another embodiment, at least two of the area of the first sub-pixel SPX1, the area of the second sub-pixel SPX2, and the area of the third sub-pixel SPX3 may be substantially the same and another one and the at least two areas of the area of the first sub-pixel SPX1, the area of the second sub-pixel SPX2, and the area of the third sub-pixel SPX3 may be different. In another embodiment, the area of the first sub-pixel SPX1, the area of the second sub-pixel SPX2, and the area of the third sub-pixel SPX3 may be different from each other.

FIG. 4 is a schematic diagram of an equivalent circuit illustrating a sub-pixel included in the pixel of FIGS. 2 and 3 according to an embodiment. The sub-pixel SPX shown in FIG. 4 may be one of the sub-pixels SPX1 to SPX3 included in the pixel PX of FIGS. 2 and 3. The sub-pixels SPX1 to SPX3 may have structures (or circuits) substantially identical to or similar to each other.

Referring to FIG. 4, the sub-pixel SPX may be electrically connected to a gate line GL, a data line DL, a first power line PL1, and a second power line PL2. The sub-pixel SPX may be further electrically connected to at least another power line (not shown) and/or signal line (not shown).

A gate signal (or a scan signal) may be supplied to the gate line GL, a data signal may be supplied to the data line DL, a voltage of first power VDD may be applied to the first power line PL1, and a voltage of second power VSS may be applied to the second power line PL2. The first power VDD and the second power VSS may have different potentials.

The sub-pixel SPX may include a light emitting element ED for generating light of a luminance corresponding to each data signal. The sub-pixel SPX may further include a pixel circuit PC for driving the light emitting element ED.

The pixel circuit PC may be electrically connected to the gate line GL and the data line DL, and may be electrically connected between the first power line PL1 and the light emitting element ED.

The pixel circuit PC may include at least one transistor and a capacitor Cst. For example, the pixel circuit PC may include a first transistor M1, a second transistor M2, and the capacitor Cst.

The first transistor M1 may be electrically connected between the first power line PL1 and a second node N2. The second node N2 may be a node to which the pixel circuit PC and the light emitting element ED are electrically connected. For example, the second node N2 may be a node where an electrode (for example, a source electrode) of the first transistor M1 and the light emitting element ED are electrically connected to each other. A gate electrode of the first transistor M1 may be electrically connected to a first node N1. The first transistor M1 may control a driving current supplied to the light emitting element ED in response to a voltage of the first node N1. For example, the first transistor M1 may be a driving transistor of the sub-pixel SPX.

The second transistor M2 may be electrically connected between the data line DL and the first node N1. A gate electrode of the second transistor M2 may be electrically connected to the gate line GL. The second transistor M2 may be turned on in case that a gate signal of a gate-on voltage (for example, a logic high voltage or a high level voltage) is supplied from the gate line GL, to connect the data line DL and the first node N1.

A data signal of a corresponding frame may be supplied to the data line DL for each frame period, and the data signal may be transferred to the first node N1 through the second transistor M2 during a period in which the gate signal of the gate-on voltage is supplied. For example, the second transistor M2 may be a switching transistor for transferring each data signal to an inside of the sub-pixel SPX.

A first electrode of the capacitor Cst may be connected to the first node N1, and a second electrode of the capacitor Cst may be connected to the second node N2. The capacitor Cst may be charged with a voltage corresponding to the data signal supplied to the first node N1 during each frame period.

In FIG. 4, both of the first and second transistors M1 and M2 included in the pixel circuit PC may be n-type transistors, but the disclosure is not limited thereto. In another embodiment, at least one of the first and second transistors M1 and M2 may be a p-type transistor. A structure and a driving method of the sub-pixel SPX may be variously changed according to an embodiment.

The pixel circuit PC may further include other circuit elements such as an initialization transistor (or a sensing transistor) for initializing an anode electrode of the light emitting element ED, a compensation transistor for compensating for a threshold voltage or the like of the first transistor M1, an initialization transistor for initializing the voltage of the first node N1, an emission control transistor for controlling a period in which the driving current is supplied to the light emitting element ED, a boosting capacitor for boosting the voltage of the first node N1, the like, or a combination thereof.

The light emitting element ED may emit light with a luminance corresponding to the driving current supplied through the pixel circuit PC. The light emitting element ED may be electrically connected between the first transistor M1 and the second power line PL2. A first electrode of the light emitting element ED may be electrically connected to an electrode (or the second node N2) of the first transistor M1, and a second electrode of the light emitting element ED may be electrically connected to the second power line PL2. The first electrode of the light emitting element ED may be an anode electrode, and the second electrode of the light emitting element ED may be a cathode electrode. The light emitting element ED may be an inorganic light emitting element including the first electrode, the second electrode, and an inorganic semiconductor disposed between the first electrode and the second electrode. For example, the light emitting element ED may be a micro light emitting diode (LED) formed of an inorganic semiconductor, but the disclosure is not limited thereto.

In FIG. 4, the sub-pixel SPX may include only one light emitting element ED, but the disclosure is not limited thereto. In another embodiment, the sub-pixel SPX may further include at least one light emitting element electrically connected to the light emitting element ED in parallel. In another embodiment, the sub-pixel SPX may further include at least one light emitting element connected to the light emitting element ED in series. The number, type, and/or structure of the light emitting elements ED configuring an effective light source of the sub-pixel SPX may be changed according to an embodiment.

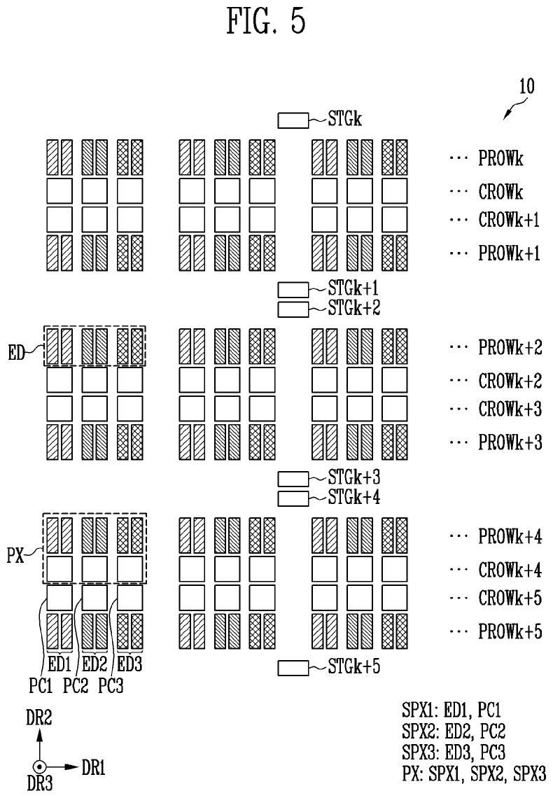

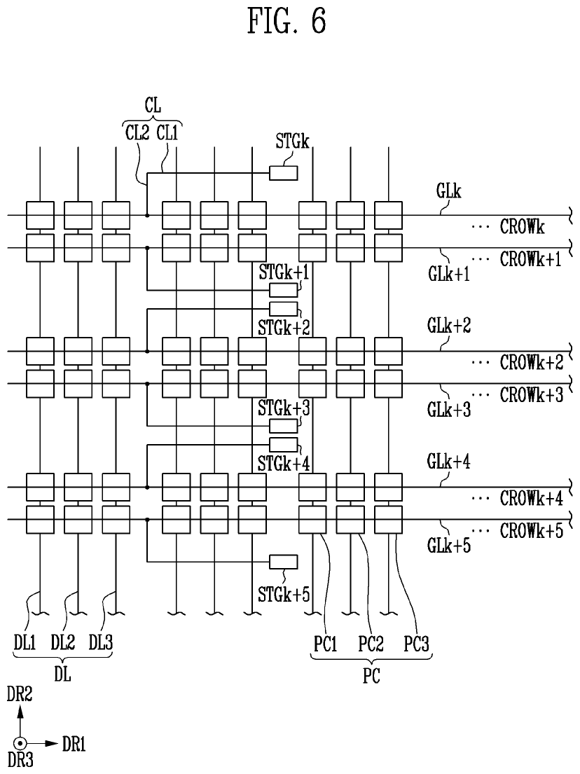

FIG. 5 is a schematic plan view illustrating the display device of FIG. 1 according to an embodiment. FIG. 6 is a schematic diagram illustrating a connection relationship between a pixel circuit and a stage included in the display device of FIG. 5. Multiple stages may configure at least one gate driver (or scan driver).

Referring to FIGS. 1 to 6, the display device 10 may include a pixel PX, and the pixel PX may include first to third sub-pixels SPX1 to SPX3.

The first sub-pixel SPX1 may include a first light emitting element ED1 and a first pixel circuit PC1, and the first pixel circuit PC1 may supply a driving current to the first light emitting element ED1. The first pixel circuit PC1 may be positioned in the second direction DR2 with respect to the first light emitting element ED1, and the first pixel circuit PC1 may be electrically connected to the first light emitting element ED1. The second sub-pixel SPX2 may include a second light emitting element ED2 and a second pixel circuit PC2, and the second pixel circuit PC2 may supply a driving current to the second light emitting element ED2. The second pixel circuit PC2 may be positioned in the second direction DR2 with respect to the second light emitting element ED2, and the second pixel circuit PC2 may be electrically connected to the second light emitting element ED2. The third sub-pixel SPX3 may include a third light emitting element ED3 and a third pixel circuit PC3, and the third pixel circuit PC3 may supply a driving current to the third light emitting element ED3. The third pixel circuit PC3 may be positioned in the second direction DR2 with respect to the third light emitting element ED3, and the third pixel circuit PC3 may be electrically connected to the third light emitting element ED3.

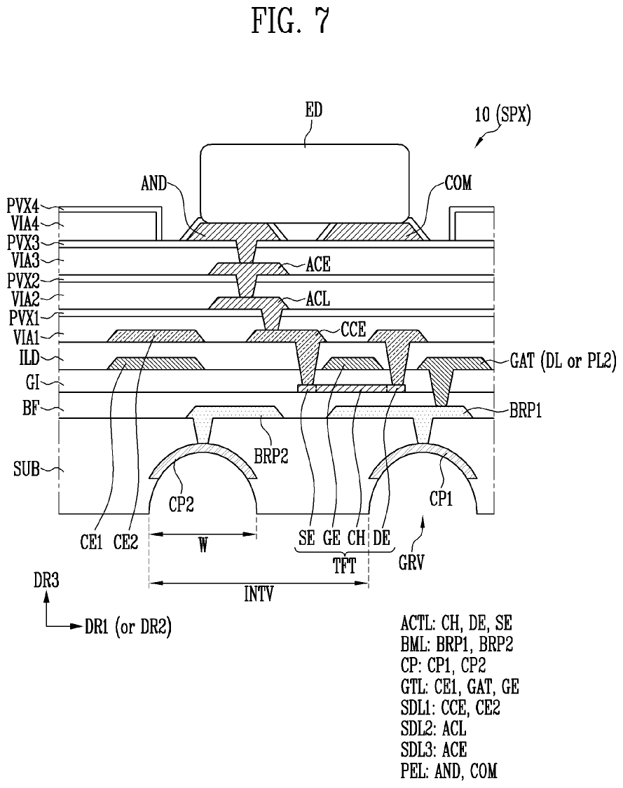

According to an embodiment, each of the first to third sub-pixels SPX1 to SPX3 may include two light emitting elements. For example, each of the first to third sub-pixels SPX1 to SPX3 may include a light emitting element (e.g., a main light emitting element) and another light emitting element (e.g., a repair light emitting element), but the disclosure is not limited thereto. In another embodiment, each of the first to third sub-pixels SPX1 to SPX3 may include three or more light emitting elements. The first to third light emitting elements ED1 to ED3 shown in FIG. 5 may be electrodes (for example, an anode electrode and a cathode electrode) of each of the first to third light emitting elements ED1 to ED3, and the electrodes of each of the first to third light emitting elements ED1 to ED3 will be described below with reference to FIG. 7.

Based on the light emitting elements ED1 to ED3, the pixels PX may be arranged to have a uniform pixel pitch. The light emitting elements ED1 to ED3 may be arranged in multiple pixel rows. For example, the light emitting elements ED1 to ED3 may be arranged in k-th to (k+5)-th pixel rows POWk, POWk+1, POWk+2, POWk+3, POWk+4, and PROWk+5 (where k is a positive integer). The pixel circuits PC1 to PC3 may be arranged in multiple circuit rows. The pixel circuits PC1 to PC3 may be arranged in k-th to (k+5)-th circuit rows CROWk, CROWk+1, CROWk+2, CROWk+3, CROWk+4, and CROWk+5.

The k-th pixel row PROWk may be disposed adjacent to the k-th circuit row CROWk in a direction opposite to the second direction DR2, and the (k+1)-th pixel row PROWk+1 may be disposed adjacent to the (k+1)-th circuit row CROWk+1 in the second direction DR2. The k-th and (k+1)-th circuit rows CROWk and CROWk+1 may be disposed between the k-th and (k+1)-th pixel rows PROWk and PROWk+1. Similarly, the (k+2)-th pixel row PROWk+2 may be disposed adjacent to the (k+2)-th circuit row CROWk+2 in the direction opposite to the second direction DR2, and the (k+3)-th pixel row PROWk+3 may be disposed adjacent to the (k+3)-th circuit row CROWk+3 in the second direction DR2. The (k+2)-th and (k+3)-th circuit rows CROWk+2 and CROWk+3 may be disposed between the (k+2)-th and (k+3)-th pixel rows PROWk+2 and PROWk+3. Similarly, the (k+4)-th pixel row PROWk+4 may be disposed adjacent to the (k+4)-th circuit row CROWk+4 in the direction opposite to the second direction DR2, and the (k+5)-th pixel row PROWk+5 may be disposed adjacent to the (k+5)-th circuit row CROWk+5 in the second direction DR2. The (k+4)-th and (k+5)-th circuit rows CROWk+4 and CROWk+5 may be disposed between the (k+4)-th and (k+5)-th pixel rows PROWk+4 and PROWk+5.

A k-th stage STGk may be disposed on an upper side of the k-th circuit row CROWk and the k-th pixel row PROWk. The k-th stage STGk may supply a gate signal to a k-th gate line GLk electrically connected to the pixel circuits PC1, PC2, and PC3 of the k-th circuit row CROWk. The k-th stage STGk may be electrically connected to the k-th gate line GLk through a connection line CL. For example, the k-th stage STGk may be electrically connected to the k-th gate line GLk through a first connection line CL1 extending in the first direction DR1 and a second connection line CL2 extending in the second direction DR2.

A (k+1)-th stage STGk+1 and a (k+2)-th stage STGk+2 may be disposed between the (k+1)-th pixel row POWk+1 and the (k+2)-th pixel row PROWk+2. The (k+1)-th stage STGk+1 may be disposed on a lower side of the (k+1)-th circuit row CROWk+1 and the (k+1)-th pixel row PROWk+1. The (k+1)-th stage STGk+1 may supply a gate signal to a (k+1)-th gate line GLk+1 electrically connected to the pixel circuits PC of the (k+1)-th circuit row CROWk+1. The (k+1)-th stage STGk+1 may be electrically connected to the (k+1)-th gate line GLk+1 through the connection line CL.

A (k+2)-th stage STGk+2 may be disposed on an upper side of the (k+2)-th circuit row CROWk+2 and the (k+2)-th pixel row PROWk+2. The (k+2)-th stage STGk+2 may supply a gate signal to the (k+2)-th gate line GLk+2 electrically connected to the pixel circuits PC of the (k+2)-th circuit row CROWk+2. The (k+2)-th stage STGk+2 may be electrically connected to the (k+1)-th gate line GLk+2 through the connection line CL.

A (k+3)-th stage STGk+3 and a (k+4)-th stage STGk+4 may be disposed between the (k+3)-th pixel row PROWk+3 and the (k+4)-th pixel row PROWk+4. The (k+3)-th stage STGk+3 may be disposed on a lower side of the (k+3)-th circuit row CROWk+3 and the (k+3)-th pixel row PROWk+3. The (k+3)-th stage STGk+3 may supply a gate signal to a (k+3)-th gate line GLk+3 electrically connected to the pixel circuits PC of the (k+3)-th circuit row CROWk+3. The (k+3)-th stage STGk+3 may be electrically connected to the (k+3)-th gate line GLk+3 through the connection line CL.

The (k+4)-th stage STGk+4 may be disposed on an upper side of the (k+4)-th circuit row CROWk+4 and the (k+4)-th pixel row PROWk+4. The (k+4)-th stage STGk+4 may supply a gate signal to a (k+4)-th gate line GLk+4 electrically connected to the pixel circuits PC of the (k+4)-th circuit row CROWk+4. The (k+4)-th stage STGk+4 may be electrically connected to the (k+4)-th gate line GLk+4 through the connection line CL.

A (k+5)-th stage STGk+5 may be disposed on a lower side of the (k+5)-th circuit row CROWk+5 and the (k+5)-th pixel row PROWk+5. The (k+5)-th stage STGk+5 may supply a gate signal to a (k+5)-th gate line GLk+5 electrically connected to the pixel circuits PC of the (k+5)-th circuit row CROWk+5. The (k+5)-th stage STGk+5 may be electrically connected to the (k+5)-th gate line GLk+5 through the connection line CL.

The data line DL may include first to third data lines DL1 to DL3. The first data line DL1 may supply a data voltage to multiple first pixel circuits PC1 disposed in a same column. The second data line DL2 may supply a data voltage to multiple second pixel circuits PC2 disposed in a same column. The third data line DL3 may supply a data voltage to multiple third pixel circuits PC3 disposed in a same column.

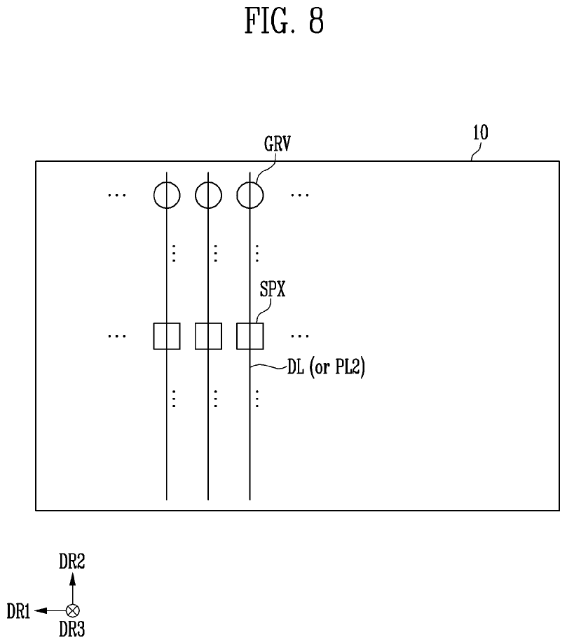

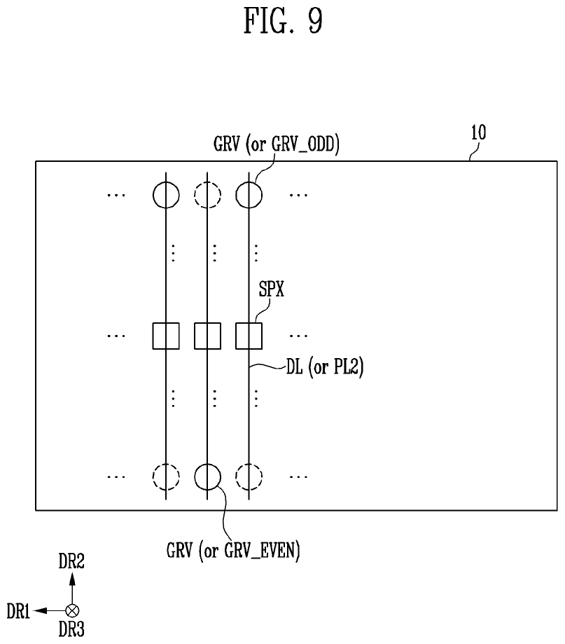

FIG. 7 is a schematic cross-sectional view illustrating the display device of FIG. 1 according to an embodiment. FIG. 7 illustrates a simplified cross-sectional view of the display device 10 based on the sub-pixel SPX. FIGS. 8 and 9 are schematic bottom views of the display device illustrating a groove included in the display device of FIG. 7.

Referring to FIGS. 1 to 7, the sub-pixel SPX (or the display device 10, or the display panel) may include a substrate SUB (or a base layer), a lower electrode layer BML, a buffer layer BF, an active layer ACTL, a gate insulating layer GI, a gate layer GTL, an interlayer insulating layer ILD, a first source metal layer SDL1, a first via layer VIA1, a first protective layer PVX1, a second source metal layer SDL2, a second via layer VIA2, a second protective layer PVX2, a third source metal layer SDL3, a third via layer VIA3, a third protective layer PVX3, a pixel electrode layer PEL, a fourth via layer VIA4, and a fourth protective layer PVX4.

The substrate SUB may be a base substrate or a base member for supporting the display device 10. The substrate SUB may be a flexible substrate that is bendable, foldable, rollable, or the like, and the substrate SUB may include an insulating material such as a polymer resin including polyimide (PI) or the like. The substrate SUB may have a single-layer structure or a multi-layer structure.

In embodiments, a groove GRV may be formed on a lower surface of the substrate SUB. For example, the groove GRV may have a shape in which the lower surface of the substrate SUB is depressed in a third direction DR3.

In an embodiment, the groove GRV may include a curved surface. For example, at least a portion of the groove GRV may be a curved surface. For example, referring to FIG. 7, in a cross-sectional view, the groove GRV may have a semicircular or semielliptical shape. However, the disclosure is not limited thereto, and in another embodiment, in a cross-sectional view, the groove GRV may have a rectangular or polygonal shape.

In an embodiment, referring to FIGS. 8 and 9, the groove GRV may have a circular shape in a plan view. However, the disclosure is not limited thereto, and in another embodiment, the groove GRV may have a shape of an ellipse, a quadrangle of which a corner is rounded, or the like in a plan view.

In an embodiment, the grooves GRV may be repeatedly arranged with an interval INTV corresponding to at least one sub-pixel SPX in the first direction DR1 or the second direction DR2. For example, the interval INTV may be in a range of about 10 μm to about 100 μm.

In an embodiment, the groove GRV may be arranged in correspondence with an arrangement of lines connected to the sub-pixels SPX. Mutually independent signals may be applied to the lines, and for example, the lines may include the data line DL. However, the disclosure is not limited thereto, and in another embodiment, the lines may include a line commonly electrically connected to the sub-pixel SPX, such as the second power line PL2 or the like. For example, referring to FIG. 8, in case that the data line DL (or the second power line PL2) electrically connected to the sub-pixel SPX is arranged in the first direction DR1, the groove GRV may be repeatedly arranged in the first direction DR1 in correspondence with each data line DL (or each second power line PL2). However, a position of the groove GRV in the second direction DR2 is not particularly limited thereto.

Referring to FIG. 8, a groove GRV may be disposed corresponding to a line (for example, a data line DL), but the disclosure is not limited thereto. For example, referring to FIG. 9, multiple grooves GRV may be disposed corresponding to a line (for example, a data line DL) or a groove GRV corresponding to a line may be repeatedly arranged in the second direction DR2. In another embodiment, in case that the groove GRV is disposed in multiple rows, only a groove GRV corresponding to a portion of lines (for example, an odd-numbered groove GRV_ODD corresponding to an odd-numbered line) may be disposed in a row (e.g., a specific row), and only a groove GRV corresponding to another line (for example, an even-numbered groove GRV_EVEN corresponding to an even-numbered line) may be disposed in another row. However, the disclosure is not limited thereto, for example, based on a line (or a sub-pixel SPX), the number of corresponding grooves GRV, a position in a plan view, and the like may be freely changed.

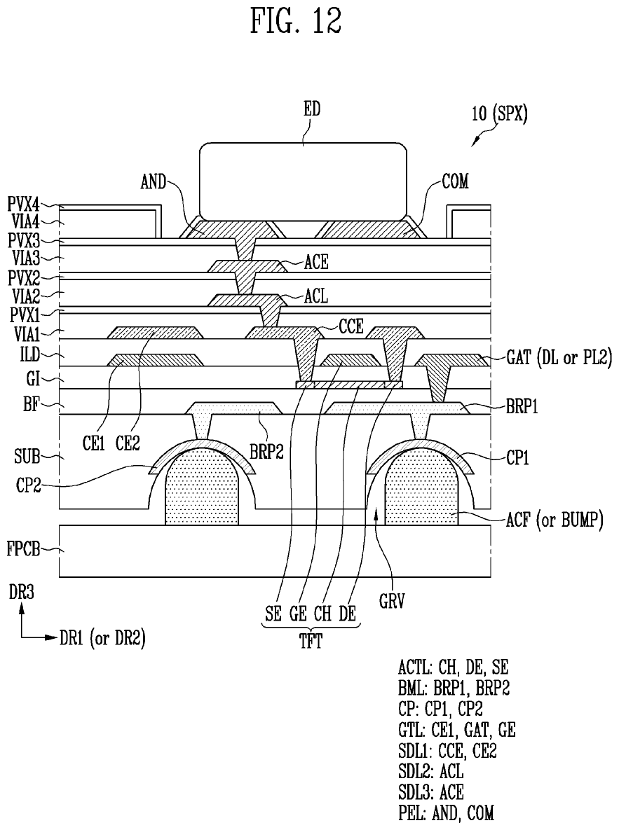

Referring to FIG. 7 again, a width W of the first direction DR1 or the second direction DR2 of the groove GRV may be less than the interval INTV. For example, the width W of the groove GRV may be in a range of about 5 μm to about 50 μm. However, the disclosure is not limited thereto. The width W of the groove GRV may be variously changed within a range in which a conductive pattern CP and a circuit board (see, e.g., FPCB of FIG. 12) may be stably connected through an anisotropic conductive film (see, e.g., ACF of FIG. 12) or a bump (see, e.g., BUMP of FIG. 12). The width W of the groove GRV may be variously changed according to the number of conductive patterns CP provided in the groove GRV.

The conductive pattern CP (or a connection pattern) may be disposed in the groove GRV. The conductive pattern CP may include a conductive material. For example, the conductive pattern CP may include a conductive material such as copper (Cu), molybdenum (Mo), tungsten (W), aluminum neodymium (AlNd), titanium (Ti), aluminum (Al), silver (Ag), the like, and an alloy thereof. The conductive pattern CP may have a single layer or multiple layers. For example, the conductive pattern CP may have a stack structure of aluminum and titanium (Ti/Al/Ti), a stack structure of copper and titanium (Ti/Cu), or the like.

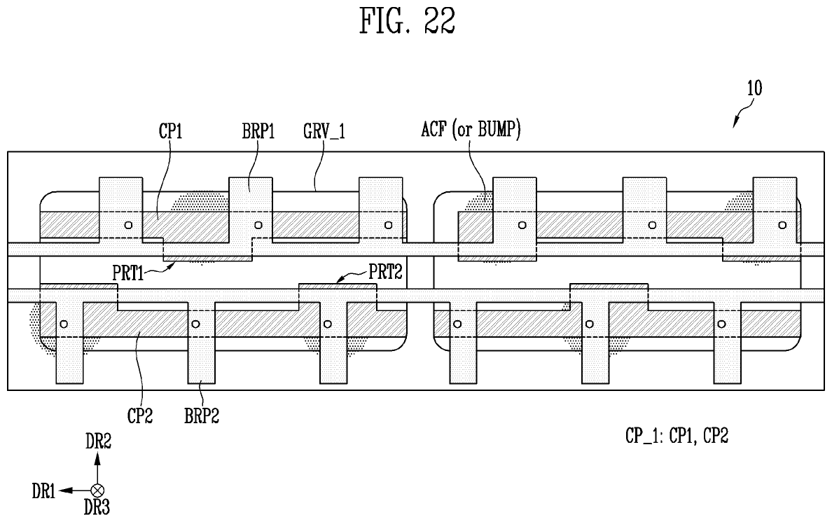

In an embodiment, one conductive pattern CP may be disposed in correspondence with one groove GRV, but the disclosure is not limited thereto. In another embodiment, multiple conductive patterns may be disposed in one groove GRV, and will be described below with reference to FIG. 22.

In an embodiment, the conductive pattern CP may include a curved surface corresponding to the groove GRV. At least a portion of the groove GRV may be defined by a lower surface of the conductive pattern CP. Referring to FIG. 7, the conductive pattern CP may define a portion of the groove GRV, and a portion of the substrate SUB may define a remainder of the groove GRV.

An independent conductive pattern CP (or each conductive pattern) may be disposed in each groove GRV. For example, a first conductive pattern CP1 may be disposed in a groove GRV, a second conductive pattern CP2 may be disposed in another groove GRV, and the first conductive pattern CP1 and the second conductive pattern CP2 may be electrically separated or insulated (or disconnected).

The lower electrode layer BML may be disposed on the substrate SUB. The lower electrode layer BML may include a conductive material or the like.

The lower electrode layer BML may include a first bridge pattern BPR1 and a second bridge pattern BRP2. The first bridge pattern BRP1 may be electrically connected to the first conductive pattern CP1 through a contact hole passing through the substrate SUB (or extending from an upper surface of the substrate SUB to the groove GRV). Similarly, the second bridge pattern BRP2 may be electrically connected to the second conductive pattern CP2 through a contact hole passing through the substrate SUB.

The buffer layer BF (also referred to as a first insulating layer) may be disposed on a surface of the substrate SUB and cover the lower electrode layer BML. The buffer layer BF may prevent penetration of air or moisture. The buffer layer BF may be an insulating layer including an inorganic material. For example, the buffer layer BF may include an inorganic material including at least one of silicon nitride (SiNₓ), and metal oxides such as silicon oxide (SiOₓ), silicon oxynitride (SiOₓN_{y}), and aluminum oxide (AlOₓ). In another embodiment, the buffer layer BF may be omitted according to a material, a process condition, or the like of the substrate SUB.

The active layer ACTL may be disposed on the buffer layer BF. In an embodiment, the active layer ACTL may include a silicon semiconductor such as polycrystalline silicon, single crystal silicon, low-temperature polycrystalline silicon, amorphous silicon, the like, or a combination thereof. In another embodiment, the active layer ACTL may include an oxide semiconductor or the like.

The active layer ACTL may include a channel CH, a first electrode SE, and a second electrode DE of a transistor TFT. The transistor TFT may be a transistor included in the pixel circuit (see, e.g., PC of FIG. 4), and for example, the transistor TFT may be the first transistor (see, e.g., M1 of FIG. 4). The channel CH of the transistor TFT may be an area overlapping a gate electrode GE of the transistor TFT in the third direction DR3, which is a thickness direction of the substrate SUB (or in a plan view). The first electrode SE of the transistor TFT may be disposed on a side of the channel CH, and the second electrode DE may be disposed on another side of the channel CH. The first electrode SE and the second electrode DE of the transistor TFT may be areas that do not overlap the gate electrode GE in the third direction DR3 (or in a plan view). The channel CH of the transistor TFT may be a semiconductor pattern in which an impurity is not doped and may be an intrinsic semiconductor. The first electrode SE and the second electrode DE of the transistor TFT may be semiconductor patterns in which an impurity is doped.

The gate insulating layer GI (also referred to as one of a second insulating layer) may be disposed on the active layer ACTL. The gate insulating layer GI may be an insulating layer including an inorganic material.

The gate layer GTL may be disposed on the gate insulating layer GI. The gate layer GTL may include a conductive material and may have a single layer or multiple layers.

The gate layer GTL may include the gate electrode GE of the transistor TFT and a first capacitor electrode CE1, (in addition to other electrodes GAT (or other lines)). For example, the other electrodes GAT may include the data line DL and the second power line PL2, or may be electrically connected to the data line DL and the second power line PL2. The other electrode GAT may be electrically connected to the first bridge pattern BRP1 through a contact hole passing through the gate insulating layer GI. The other electrode GAT may be electrically connected to the first conductive pattern CP1 through the first bridge pattern BRP1.

The interlayer insulating layer ILD (also referred to as another one of a second insulating layer) may be disposed on the gate layer GTL. The interlayer insulating layer ILD may be an insulating layer including an inorganic material.

The first source metal layer SDL1 may be disposed on the interlayer insulating layer ILD. The first source metal layer SDL1 may include a conductive material and may have a single layer or multiple layers.

The first source metal layer SDL1 may include a connection electrode CCE and a second capacitor electrode CE2. The connection electrode CCE may be electrically connected to the first electrode SE (or the second electrode DE) of the transistor TFT through a contact hole passing through the interlayer insulating layer ILD and the gate insulating layer GI. The second capacitor electrode CE2 may configure the capacitor (see, e.g., Cst of FIG. 4) with the first capacitor electrode CE1.

The first via layer VIA1 (or a first planarization layer) may be disposed on the first source metal layer SDL1. The first via layer VIA1 may flatten a step difference due to the active layer ACTL, the gate layer GTL, and the first source metal layer SDL1. The first via layer VIA1 may be an insulating layer including an organic material. For example, the first via layer VIA1 may include an organic material such as an acrylic resin, an epoxy resin, a phenolic resin, a polyamide resin, a polyimide resin, the like, or a combination thereof.

The first protective layer PVX1 may be disposed on the first via layer VIAL. The first protective layer PVX1 may be an insulating layer including an inorganic material.

The second source metal layer SDL2 may be disposed on the first protective layer PVX1. The second source metal layer SDL2 may include a conductive material and may have a single layer or multiple layers.

The second source metal layer SDL2 may include an anode connection line ACL. The anode connection line ACL may be electrically connected to the connection electrode CCE through a contact hole passing through the first protective layer PVX1 and the first via layer VIA1.

In another embodiment, the first via layer VIA1 and the first protective layer PSV1 may be omitted, and the connection electrode CCE may be included in the anode connection line ACL, but the disclosure is not limited thereto. In another embodiment, the first via layer VIA1 may be omitted. For example, the anode connection line ACL may be electrically connected to the first electrode SE of the transistor TFT through a contact hole passing through the interlayer insulating layer ILD and the gate insulating layer GI.

The second via layer VIA2 may be disposed on the second source metal layer SDL2. The second via layer VIA2 may be an insulating layer including an organic material.

The second protective layer PVX2 may be disposed on the second via layer VIA2. The second protective layer PVX2 may be an insulating layer including an inorganic material.

The third source metal layer SDL3 may be disposed on the second protective layer PVX2. The third source metal layer SDL3 may include a conductive material and may have a single layer or multiple layers.

The third source metal layer SDL3 may include an anode connection electrode ACE (or a bridge electrode). The anode connection electrode ACE may be electrically connected to the anode connection line ACL through a contact hole passing through the second protective layer PVX2 and the second via layer VIA2.

The third via layer VIA3 may be disposed on the third source metal layer SDL3. The third via layer VIA3 may be an insulating layer including an organic material.

The third protective layer PVX3 may be disposed on the third via layer VIA3. The third protective layer PVX3 may be an insulating layer including an inorganic material.

The pixel electrode layer PEL may be disposed on the third protective layer PVX3. The pixel electrode layer PEL may include a pixel electrode AND (or a first pixel electrode) and a common electrode COM (or a second pixel electrode). The pixel electrode AND may be referred to as an anode electrode, and the common electrode COM may be referred to as a cathode electrode.

The pixel electrode AND may be electrically connected to the anode connection electrode ACE through a contact hole passing through the third protective layer PVX3 and the third via layer VIA3. Through the anode connection electrode ACE, the anode connection line ACL, and the connection electrode CCE, the pixel electrode AND may be electrically connected to the first electrode SE of the transistor TFT. Accordingly, a pixel voltage (or a driving current) controlled by the transistor TFT may be applied to the pixel electrode AND.

Similarly to the pixel electrode AND, the common electrode COM may be electrically connected to a power line (for example, the second power line PL2) through a contact hole passing through the third protective layer PVX3 and the third via layer VIA3. Through the third protective layer PVX3 and the third via layer VIA3, a power voltage of a power line may be applied to the common electrode COM.

The pixel electrode AND and the common electrode COM may include a metal material having high reflectance such as a stack structure of aluminum and titanium (Ti/Al/Ti), a stack structure of aluminum and ITO (ITO/Al/ITO), an APC alloy, a stack structure of an APC alloy and ITO (ITO/APC/ITO), or the like. The APC alloy may be an alloy of silver (Ag), palladium (Pd), and copper (Cu).

The fourth via layer VIA4 (or bank, or a pixel definition layer) may be disposed on the third protective layer PVX3. The fourth via layer VIA4 may be an insulating layer including an organic material. The fourth via layer VIA4 may include an opening, and at least a portion of the pixel electrode AND and the common electrode COM may be exposed through the opening of the fourth via layer VIA4.

The fourth protective layer PVX4 may be disposed on the third protective layer PVX3 (and the fourth via layer VIA4). The fourth protective layer PVX4 may cover an edge of the pixel electrode AND and an edge of the common electrode COM. The fourth protective layer PVX4 may be an insulating layer including an inorganic material.

The light emitting element ED may be disposed in the opening of the fourth via layer VIA4 (and the fourth protective layer PVX4). The light emitting element ED may be disposed on the pixel electrode AND and the common electrode COM which are not covered by the fourth protective layer PVX4 (or exposed by the fourth protective layer PVX4).

For example, the light emitting element ED may be a flip chip type of micro LED. The light emitting element ED may be formed of an inorganic material such as GaN or the like. Each of lengths of the first direction DR1, the second direction DR2, and the third direction DR3 of the light emitting element ED may be in a range of several to hundreds of m. For example, each of the lengths of the first direction DR1, the second direction DR2, and the third direction DR3 of the light emitting element ED may be less than or equal to about 100 μm.

In FIG. 7, the data line DL, the second power line PL2, or a line connected to the data line DL and the second power line PL2 may be disposed on the gate layer GTL, but the disclosure is not limited thereto. For example, lines including the data line DL and the second power line PL2 may be disposed on at least one of the first source metal layer SDL1, the second source metal layer SDL2, and the third source metal layer SDL3.

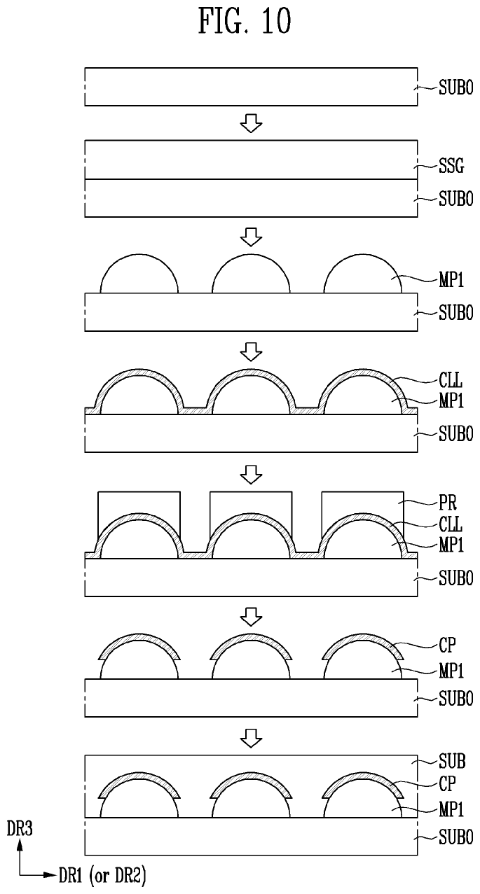

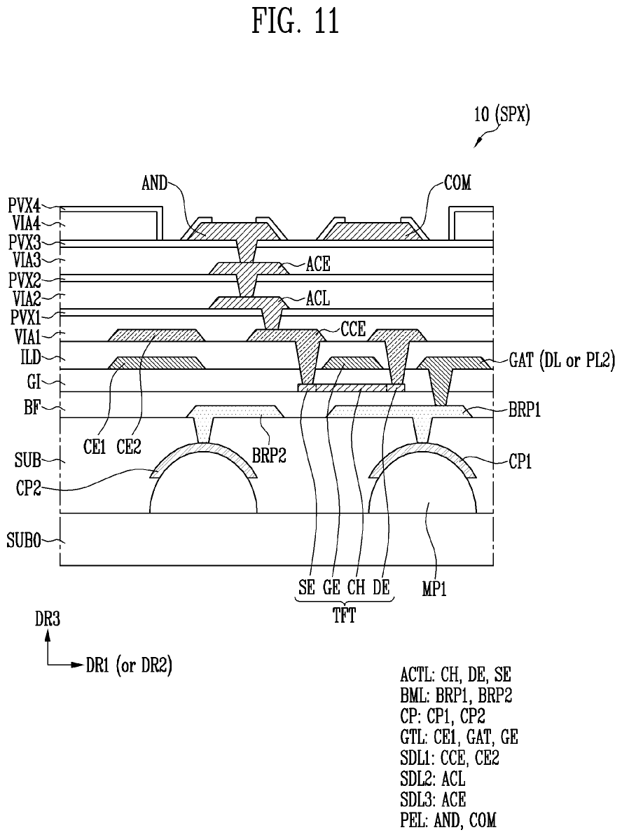

FIGS. 10 and 11 are schematic cross-sectional views illustrating a method of manufacturing the display device of FIG. 7.

Referring to FIGS. 7, 10, and 11, a carrier substrate SUB0 may be prepared. The carrier substrate SUB0 may be a rigid substrate including a glass material, but the disclosure is not limited thereto.

A sacrificial layer SSG may be formed on the carrier substrate SUB0. The sacrificial layer SSG may include silica sol-gel (Si sol-gel), a polymer organic material, or the like.

A first mold pattern MP1 may be formed from the sacrificial layer SSG. For example, the first mold pattern MP1 may be formed by stamping the sacrificial layer SSG using a mold having a groove corresponding to the first mold pattern MP1. A shape, an interval, a size, a position, an arrangement, and the like of the first mold pattern MP1 may respectively correspond to a shape, an interval, a size, a position, an arrangement and the like of the groove GRV described with reference to FIGS. 7 to 9.

A conductive layer CLL may be formed on the carrier substrate SUB0 to cover the first mold pattern MPL.

A photoresistor PR may be formed on the conductive layer CLL. The photoresistor PR may be disposed to correspond to a conductive pattern CP.

The conductive pattern CP may be formed from the conductive layer CLL by etching a portion of the conductive layer CLL exposed by the photoresistor PR. After forming the conductive pattern CP, the photoresistor PR may be removed.

The substrate SUB (or the base layer) may be formed on the carrier substrate SUB0 to cover the conductive pattern CP.

After forming the substrate SUB, referring to FIG. 11, on the substrate SUB, the lower electrode layer BML, the buffer layer BF, the active layer ACTL, the gate insulating layer GI, the gate layer GTL, the interlayer insulating layer ILD, the first source metal layer SDL1, the first via layer VIA1, the first protective layer PVX1, the second source metal layer SDL2, the second via layer VIA2, the second protective layer PVX2, the third source metal layer SDL3, the third via layer VIA3, the third protective layer PVX3, the pixel electrode layer PEL, the fourth via layer VIA4, and the fourth protective layer PVX4 may be sequentially formed.

The carrier substrate SUB0 may be removed or separated from the display device 10 (or the substrate SUB). For example, the carrier substrate SUB0 may be removed from the display device 10 using a laser detachment device. The first mold pattern MP1 may be removed or separated from the display device 10 (or the substrate SUB) together with the carrier substrate SUB0. A groove (see, e.g., GRV of FIG. 7) corresponding to the first mold pattern MP1 may be formed on the lower surface of the substrate SUB.

After forming the groove GRV, the light emitting element (see, e.g., ED of FIG. 7) may be disposed or mounted on the pixel electrode layer PEL exposed by the fourth via layer VIA4 and the fourth protective layer PVX4, for example, on the pixel electrode AND and the common electrode COM. For example, the light emitting element ED may be formed by being grown on a semiconductor substrate such as a silicon wafer or the like. The light emitting element ED may be transferred from the silicon wafer onto the pixel electrode AND and the common electrode COM of the display device 10. In another embodiment, the light emitting element ED may be transferred onto the pixel electrode AND and the common electrode COM of the display device 10 by an electrostatic method using an electrostatic head, a stamp method using an elastic polymer material, or the like such as PDMS, silicon, or the like.

As described above, the display device 10 may be manufactured only through a front surface process of sequentially forming the substrate SUB to the pixel electrode layer PEL on the carrier substrate SUB0. For example, a rear surface process for forming a conductive pattern (for example, a connection pattern for connecting to the circuit board (see, e.g., FPCB of FIG. 12)) on a lower portion of a general substrate, or a side surface process for forming a connection line (for example, a connection line for connecting the conductive pattern to a transistor on the substrate and an insulating layer for protecting the connection line) may be unnecessary. Accordingly, the display device 10 including the conductive pattern CP exposed under the substrate SUB may be manufactured through a simpler process. Since a connection line (and insulating layer) is not disposed on a side surface of the display device 10, a dead space of the display device 10 (for example, an area where the sub-pixel SPX is not disposed at an edge of the display device 10) may be reduced, and the dead space may not substantially exist in the display device 10.

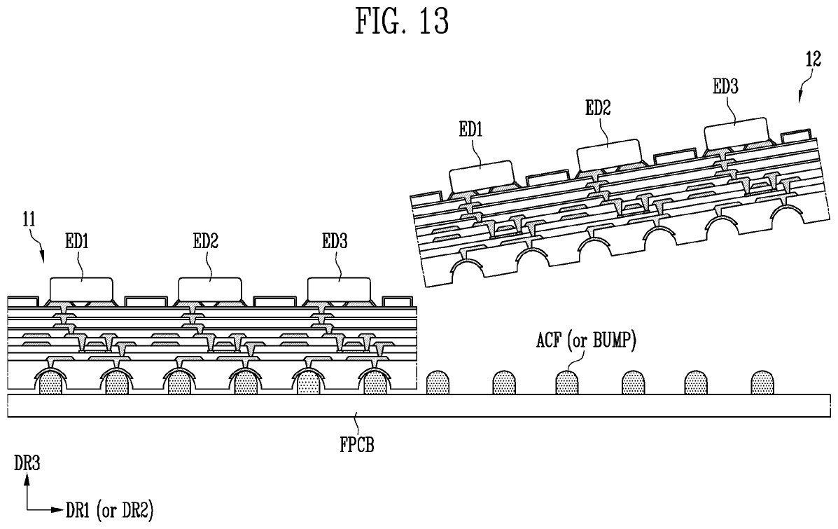

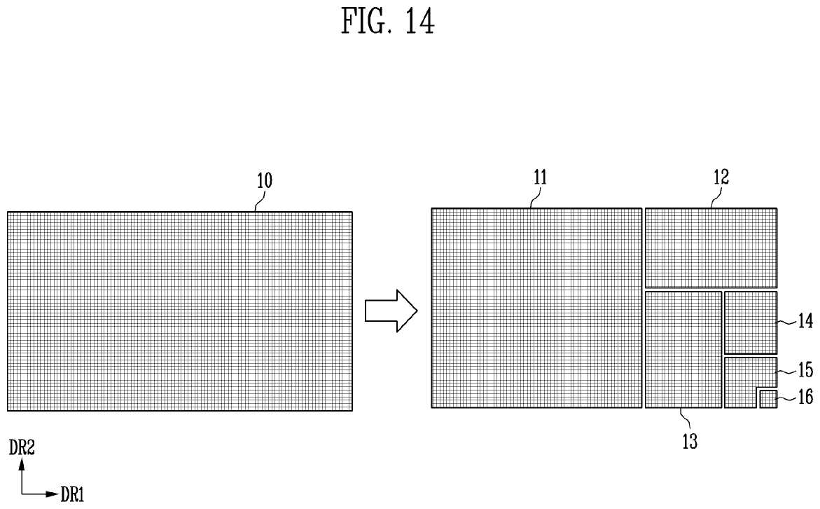

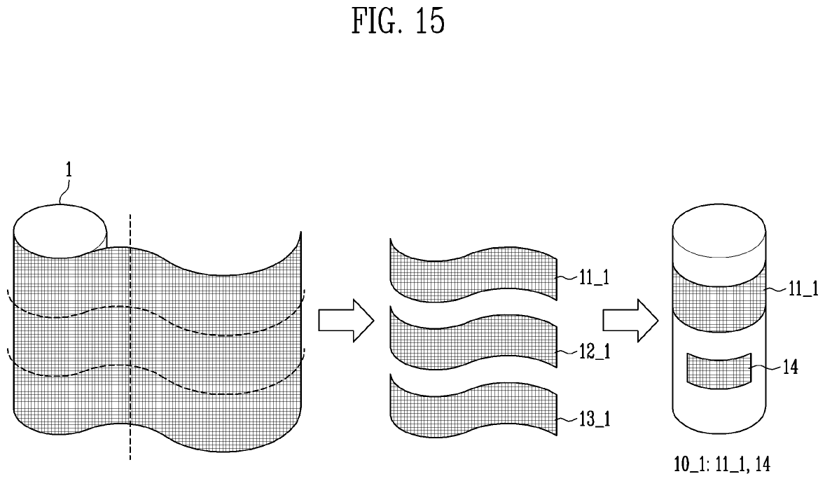

FIG. 12 is a schematic cross-sectional view illustrating the display device of FIG. 1 according to an embodiment. FIG. 13 is a schematic cross-sectional view illustrating a method of manufacturing the display device of FIG. 12. FIG. 14 is a schematic plan view illustrating the display device of FIG. 12 according to an embodiment. FIG. 15 is a schematic diagram illustrating the display device of FIG. 1 according to an embodiment.

Referring to FIGS. 1, 7, 12, 13, and 14, the display device 10 may further include the circuit board FPCB (or a circuit film).

The circuit board FPCB may be disposed below the substrate SUB and may be connected to the conductive pattern CP through an anisotropic conductive film ACF, the bump BUMP, or the like. For example, the circuit board FPCB may include lines and pads electrically connected to a driving circuit (for example, a data driver mounted on the circuit board FPCB), and the lines may be electrically connected to the conductive pattern CP through the pads and the anisotropic conductive film ACF (or the bump BUMP).

For example, referring to FIGS. 13 and 14, the display device 10 may be implemented as a tiled display device including multiple display panels 11, 12, 13, 14, 15, and 16. The display device 10 may be manufactured by mounting the display panels 11 to 16 (for example, a first display panel 11 and a second display panel 12) on the circuit board FPCB on which the anisotropic conductive film (see, e.g., ACF of FIG. 13) (or the bump (see, e.g., BUMP of FIG. 13)) is formed.

As described with reference to FIGS. 10 and 11, since a dead space does not substantially exist in the display device 10 (or the display panels 11 to 16), even though the display panels 11 to 16 of different sizes and shapes are stitched like a mosaic, there may be no misalignment (or alternateness) between the display panels 11 to 16, and the display device 10 may have a shape (e.g., a desired shape) perfectly. For example, a length of the first direction DR1 of the display device 10 may be the same in a first portion to which the first display panel 11 and the second display panel 12 are connected, a second portion to which the first display panel 11, a third display panel 13, and a fourth display panel 14 are connected, a third portion to which the first display panel 11, the third display panel 13, and a fifth display panel 15, and a fourth portion to which the first display panel 11, the third display panel 13, and the fifth display panel 15, and a sixth display panel 16 are connected. Therefore, a size, a shape, or the like of the display panels 11 to 16 configuring the display device 10 may not be required to be the same, and the shape of each of the display panels 11 to 16 may not be required to be limited to a quadrangle. For example, the shape of the display panels 11 to 16 may be atypical. Since a mother panel (or a mother board) including the display panels 11 to 16 may be substantially 100% used, (for example, compared to a case that the mother panel is not used 100%), a manufacturing cost of the display device 10 may be reduced. In case that a defect exists in a portion of the mother panel, most of the mother panel may be used for manufacturing the display device 10 except for a corresponding area where the defect exists (for example, a minimum area), and the manufacturing cost may be reduced.

In an embodiment, resolutions (for example, pixel per inch (PPI)) of at least two of the display panels 11 to 16 may be different. According to purpose of the display device 10, resolution of a portion of the display device 10 and resolution of another portion of the display device 10 may be different from each other. For example, resolution of the third display panel 13 may be greater than resolution of the first display panel 11, and resolution of the fifth display panel 15 may be lower than resolution of the first display panel 11. Since the size, the shape, and the like of the display panels 11 to 16 are not required to be the same, only a portion (e.g., a desired portion) of the display device 10 may have different resolutions.

Referring to FIG. 15, a mother panel 1 may be stored in a rollable form.

Display panels 11_1, 12_2, and 131 may be obtained by cutting only a portion (e.g., a specific portion) of the mother panel 1. As described above, since the substrate is a flexible substrate including an insulating material such as a polymer resin including polyimide (PI) or the like, each of the display panels 11_1, 12_1, and 13_1 may be bent or rolled.

For example, a display device 101 may be manufactured by attaching a first display panel 11_1 to a cylindrical column (or a column having a curved surface).

The display device 10_1 may further include a fourth display panel 14, and the fourth display panel 14 and the first display panel 11_1 may have different sizes or different shapes. The fourth display panel 14 and the first display panel 11_1 may have different resolutions.

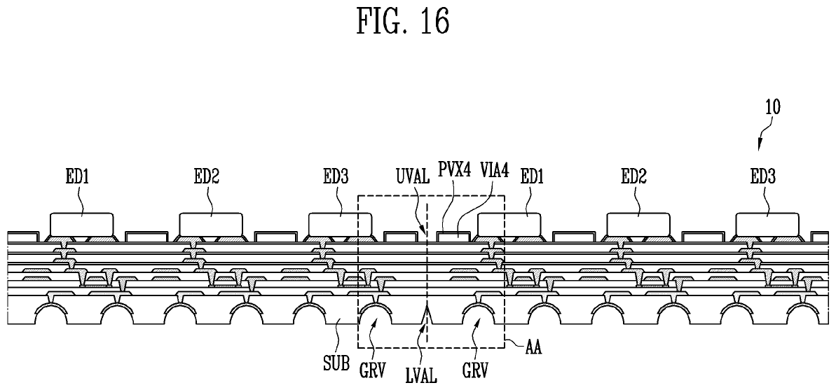

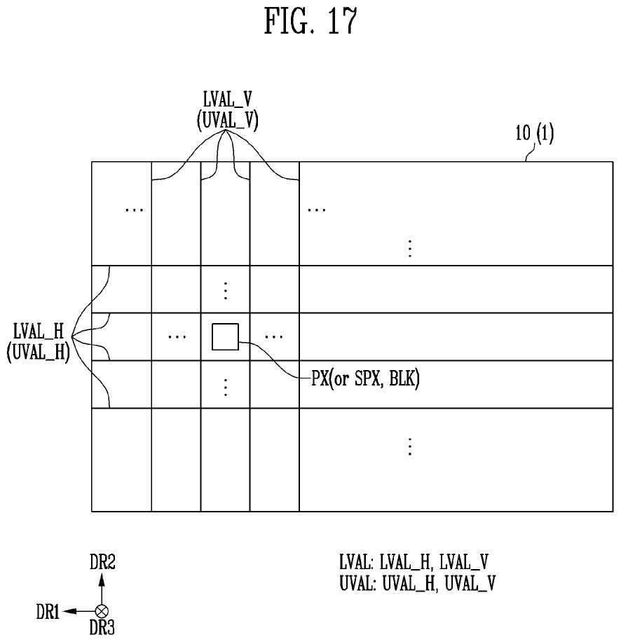

FIG. 16 is a schematic cross-sectional view illustrating the display device of FIG. 1 according to an embodiment. FIG. 16 illustrates a simplified cross-sectional view of the display device 10 based on some light emitting elements ED1 to ED3. FIG. 17 is a schematic bottom view of a display device illustrating a valley included in the display device of FIG. 16.

Referring to FIGS. 1, 7, 16, and 17, each of the light emitting elements ED1 to ED3 (or a stack structure including the same) may correspond to a sub-pixel SPX (see, e.g., FIG. 7). As described with reference to FIG. 5, the first light emitting element ED1 may correspond to the first sub-pixel SPX1, the second light emitting element ED2 may correspond to the second sub-pixel SPX2, and the third light emitting element ED3 may correspond to the third sub-pixel SPX3. The first to third light emitting elements ED1 to ED3 (or the first to third sub-pixels SPX1 to SPX3) may be included in one pixel PX. Since a structure of the sub-pixel SPX is described with reference to FIGS. 7 and 12, a description of the structure of the sub-pixel SPX is omitted, and a difference from the embodiments of FIGS. 7 and 12 is described. The embodiments of FIGS. 7 and 12 may be applied to an embodiment of FIG. 16.

On the lower surface of the substrate SUB, (in addition to the groove GRV) a first valley LVAL (or a lower valley) may be further formed. For example, similarly to the groove GRV, the first valley LVAL may have a shape in which the lower surface of the substrate SUB is depressed in the third direction DR3. A conductive pattern may not be disposed in the first valley LVAL.

In an embodiment, in a cross-sectional view, a shape of the first valley LVAL and a shape of the groove GRV may be different from each other. For example, referring to FIG. 16, in a cross-sectional view, the first valley LVAL may have a shape of an isosceles triangle. However, the disclosure is not limited thereto, and in another embodiment, in a cross-sectional view, the groove GRV may have a shape of a trapezoid, a semicircle, or the like.

In an embodiment, referring to FIG. 17, in a bottom view, the first valley LVAL may extend in the first direction DR1 and/or the second direction DR2, and the first valley LVAL may be repeatedly arranged with an interval corresponding to at least one pixel PX (or at least one light emitting element (see, e.g., ED of FIG. 7)).

For example, the first valley LVAL may include a first horizontal valley LVAL_H extending in the first direction DR1 and arranged in the second direction DR2. The first valley LVAL may include a first vertical valley LVAL_V extending in the second direction DR2 and arranged in the first direction DR1. The first horizontal valley LVAL_H and the first vertical valley LVAL_V may intersect each other, and the first valley LVAL may have a mesh structure throughout the display device 10 (or the mother panel 1).

According to an embodiment, the first valley LVAL (or the first horizontal valley LVAL_H and the first vertical valley LVAL_V) may be repeatedly arranged with an interval corresponding to a block BLK (for example, a block including multiple pixels PX) or the sub-pixel SPX.

As described above, in case that the display device 10 (or the mother panel 1) is bendable or rollable, the first valley LVAL may reduce stress due to bending, rolling, or the like of the display device 10 (or the mother panel 1), and may facilitate bending, rolling, or the like of the display device 10 (or the mother panel 1).

As described above, in case that the display device 10 (or the display panel) is obtained by cutting the mother panel 1, the first valley LVAL may facilitate cutting of the mother panel 1 (or the display device 10) together with a second valley UVAL. Since the first valley LVAL is arranged at an interval corresponding to at least one pixel PX and the mother panel 1 may be arbitrarily cut based on the first valley LVAL (or an arrangement interval of the first valley LVAL), the display device 10 having an atypical shape (for example, a polygon except for a quadrangle) in a plan view may be readily manufactured.

Referring to FIG. 16 again, the second valley UVAL exposing pixel electrodes (for example, anode or cathode electrodes contacting the light emitting elements ED1 to ED3) may be further formed on the fourth via layer VIA4 (and the fourth protective layer PVX4).

For example, referring to FIG. 16, in a cross-sectional view, the second valley UVAL may have a quadrangular shape, but the disclosure is not limited thereto. For example, in a cross-sectional view, the second valley UVAL may have a shape of an inverted trapezoid, an inverted triangle, a semicircle, or the like.

In an embodiment, referring to FIG. 17, the second valley UVAL may extend in the first direction DR1 or the second direction DR2, and the second valley UVAL may be repeatedly arranged with an interval corresponding to at least one pixel PX. For example, the second valley UVAL may correspond to the first valley LVAL. For example, the first valley LVAL and the second valley UVAL may overlap each other in the third direction DR3 (or in a plan view), or the first valley LVAL and the second valley UVAL may be positioned on a same imaginary line extending in the third direction DR3. However, the disclosure is not limited thereto.

For example, the second valley UVAL may include a second horizontal valley UVAL_H extending in the first direction DR1 and arranged in the second direction DR2. The second valley UVAL may include a second vertical valley UVAL_V extending in the second direction DR2 and arranged in the first direction DR1. The second valley UVAL may have a mesh structure throughout the display device 10 (or the mother panel 1).

According to an embodiment, the second valley UVAL (or the second horizontal valley UVAL_H and the second vertical valley UVAL_V) may be repeatedly arranged with an interval corresponding to the block BLK (for example, the block including the pixels PX) or the sub-pixel SPX.

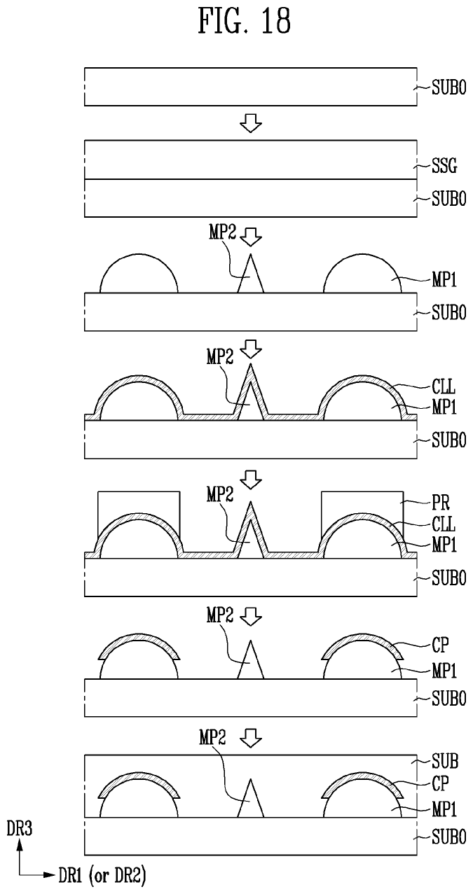

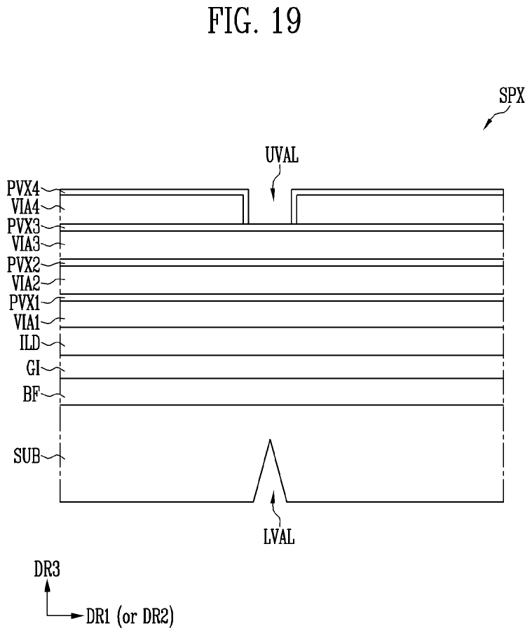

FIGS. 18 and 19 are schematic cross-sectional views illustrating a method of manufacturing the display device of FIG. 16. FIG. 18 illustrates cross sections corresponding to the embodiment of FIG. 10, and FIG. 19 illustrates a cross section corresponding to an area AA of FIG. 18.

Referring to FIGS. 10, 16, 18, and 19, the carrier substrate SUB0 may be prepared.

The sacrificial layer SSG may be formed on the carrier substrate SUB0.

The first mold pattern MP1 and a second mold pattern MP2 may be formed from the sacrificial layer SSG. For example, the first mold pattern MP1 and the second mold pattern MP2 may be formed by stamping the sacrificial layer SSG using a mold including grooves corresponding to the first mold pattern MP1 and the second mold pattern MP2. A shape, an arrangement, an interval, a size, a position, and the like of the second mold pattern MP2 may respectively correspond to a shape, an arrangement, and interval, a size, a position, and the like of the first valley LVAL described with reference to FIGS. 16 and 17.

The conductive layer CLL may be formed on the carrier substrate SUB0 to cover the first mold pattern MP1 and the second mold pattern MP2.

The photoresistor PR may be formed on the conductive layer CLL. The photoresistor PR may be disposed to correspond to the conductive pattern CP. The photoresistor PR may not be disposed on the second mold pattern MP2 or may be removed.

The conductive pattern CP may be formed from the conductive layer CLL by etching a portion of the conductive layer CLL exposed by the photoresistor PR. After forming the conductive pattern CP, the photoresistor PR may be removed.

The substrate SUB (or the base layer) may be formed on the carrier substrate SUB0 to cover the conductive pattern CP and the second mold pattern MP2.

After forming the substrate SUB, referring to FIG. 19, on the substrate SUB, the buffer layer BF, the gate insulating layer GI, the interlayer insulating layer ILD, the first via layer VIA1, the first protective layer PVX1, the second via layer VIA2, the second protective layer PVX2, the third via layer VIA3, the third protective layer PVX3, the fourth via layer VIA4, and the fourth protective layer PVX4 may be sequentially formed on the substrate SUB. As described above, the second valley UVAL corresponding to the first valley LVAL of the substrate SUB may be formed on the fourth via layer VIA4 (and the fourth protective layer PVX4).

The carrier substrate SUB0 may be removed or separated from the display device 10 (or the substrate SUB). The first mold pattern MP1 and the second mold pattern MP2 may be removed or separated from the display device 10 (or the substrate SUB) together with the carrier substrate SUB0. The groove (see, e.g., GRV of FIG. 16) corresponding to the first mold pattern MP1 and the first valley LVAL corresponding to the second mold pattern MP2 may be formed on the lower surface of the substrate SUB.

After forming the groove and the first valley LVAL, the light emitting elements (see, e.g., ED1 to ED3 of FIG. 16) may be disposed or mounted on the pixel electrode layer (see, e.g., PEL of FIG. 7) exposed by the fourth via layer VIA4 and the fourth protective layer PVX4.

As described above, the first valley LVAL may be formed together with the groove GRV.

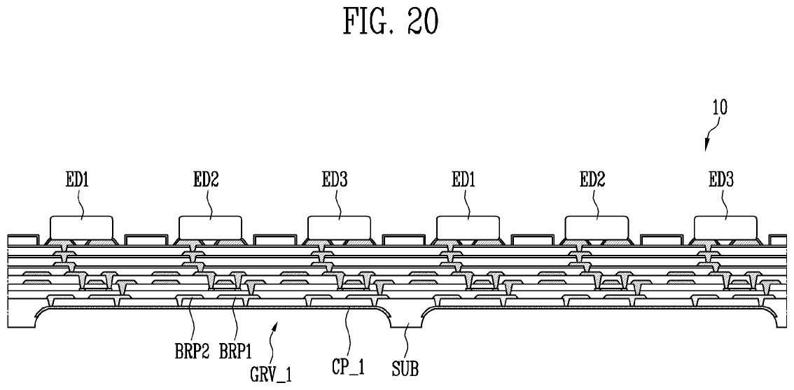

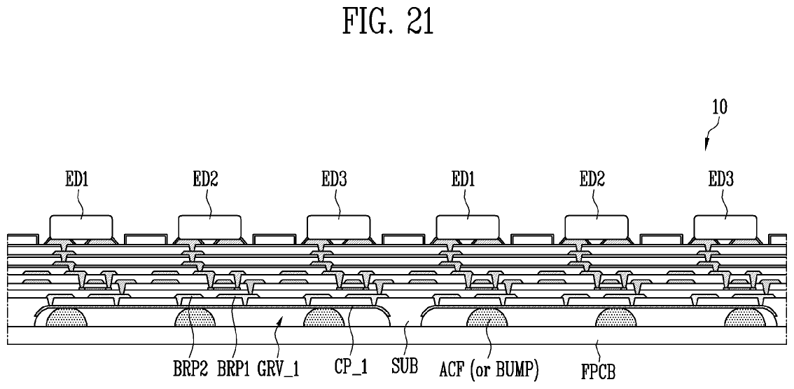

FIGS. 20 and 21 are schematic cross-sectional views illustrating the display device of FIG. 1 according to an embodiment. FIGS. 20 and 21 illustrate a simplified cross-sectional view of the display device 10 based on some light emitting elements ED1 to ED3. FIG. 22 is a schematic bottom view of the display device illustrating a groove included in the display device of FIGS. 20 and 21.

Referring to FIGS. 1, 7, 12, 20, 21, and 22, each of the light emitting elements ED1 to ED3 (or a stack structure including the same) may correspond to a sub-pixel SPX (see, e.g., FIGS. 7 and 12). As described with reference to FIG. 5, the first light emitting element ED1 may correspond to the first sub-pixel SPX1, the second light emitting element ED2 may correspond to the second sub-pixel SPX2, and the third light emitting element ED3 may correspond to the third sub-pixel SPX3. The first to third light emitting elements ED1 to ED3 (or the first to third sub-pixels SPX1 to SPX3) may be included in one pixel PX. Since a structure of the sub-pixel SPX is described with reference to FIGS. 7 and 12, a description of the structure of the sub-pixel SPX is omitted, and a difference from the embodiment of FIG. 7 (in addition to FIGS. 12 and 16) is described. The embodiment of FIG. 7 (in addition to FIGS. 12 and 16) may be applied to the embodiments of FIGS. 20 and 21.

In an embodiment, a groove GRV_1 may be formed on the lower surface of the substrate SUB. For example, the groove GRV_1 may have a shape in which the lower surface of the substrate SUB is depressed in the third direction DR3.

In an embodiment, the groove GRV_1 may include a curved surface. For example, referring to FIG. 7, in a cross-sectional view, the groove GRV_1 may have a shape of a quadrangle of which a corner is rounded. However, the disclosure is not limited thereto, and in another embodiment, in a cross-sectional view, the groove GRV_1 may have a quadrangular shape.

In an embodiment, referring to FIG. 22, in a cross-sectional view, the groove GRV_1 may have a shape of a quadrangle of which a corner is rounded. However, the disclosure is not limited thereto, and in another embodiment, in a plan view, the groove GRV_1 may have a circular shape.

In an embodiment, the groove GRV_1 may be repeatedly arranged in correspondence with at least one pixel (for example, a pixel including the first to third light emitting elements ED1 to ED3) in the first direction DR1 (and/or the second direction DR2). For example, in case that a size of the sub-pixel is small, since a stable connection between the conductive pattern CP and the circuit board FPCB may not be guaranteed only with the groove GRV of FIG. 7, the groove GRV_1 may be arranged in correspondence with at least one pixel.

Conductive patterns CP_1 (or connection patterns) may be disposed in the groove GRV_1. The conductive patterns CP_1 may include a first conductive pattern CP1 and a second conductive pattern CP2. For example, both of the first conductive pattern CP1 and the second conductive pattern CP2 may be disposed in each groove GRV_1.

In an embodiment, the first conductive pattern CP1 may be connected to multiple first bridge patterns BRP1 extending in the second direction DR2. For example, referring to FIG. 22, the first conductive pattern CP1 may be connected to three first bridge patterns BRP1 extending in the second direction DR2. The bridge patterns BPR1 may be connected to each other through a line (or a portion) extending in the first direction DR1. The bridge patterns BRP1 may be connected to multiple bridge patterns BRP1 in an adjacent groove GRV_1 through the line, but the disclosure is not limited thereto. For example, only the bridge patterns BPR1 corresponding to one groove GRV_1 may be connected to each other, and may be electrically separated or insulated from the bridge patterns BRP1 in the adjacent groove GRV_1.

Similarly to the first conductive pattern CP1, the second conductive pattern CP2 may be connected to multiple second bridge patterns BRP2 extending in the second direction DR2.

In an embodiment, each of the first conductive pattern CP1 and the second conductive pattern CP2 may include at least one of protrusions PRT1 and PRT2. For example, referring to FIG. 22, the first conductive pattern CP1 may include a first protrusion PRT1 protruding in a direction opposite to the second direction DR2, and the second conductive pattern CP2 may include a second protrusion PRT2 protruding in the second direction DR2. Each of the first protrusion PRT1 and the second protrusion PRT2 may ensure a contact area between the anisotropic conductive film ACF (or the bump BUMP) and each of the first and second conductive patterns CP1 and CP2. The first protrusion PRT1 and the second protrusion PRT2 may be misaligned with each other or alternately arranged in the first direction DR1, and a short circuit between the first conductive pattern CP1 and the second conductive pattern CP2 may be prevented.

As described above, the groove GRV_1 may be positioned corresponding to at least one pixel, and multiple conductive patterns CP_1 may be disposed in the groove GRV_1.

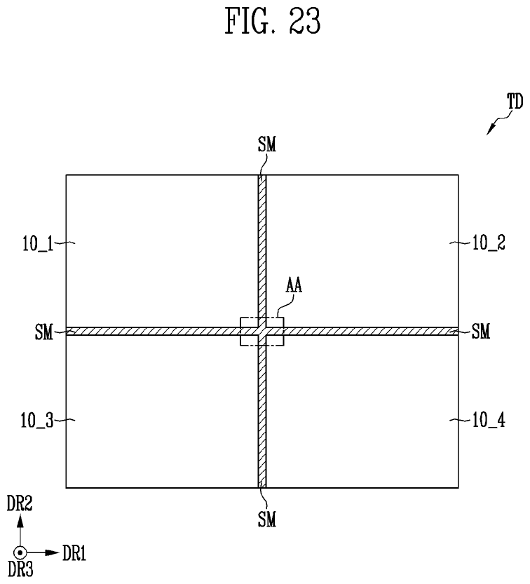

FIG. 23 is a schematic plan view illustrating a tiled display device including multiple display devices according to an embodiment.

Referring to FIG. 23, the tiled display device TD may include multiple display devices 10_1, 10_2, 10_3, and 10_4. For example, the tiled display device TD may include a first display device 10_1, a second display device 10_2, a third display device 10_3, and a fourth display device 10_4.

Each of the display devices 10_1 to 10_4 may include pixels, and the display devices 10_1 to 10_4 may be disposed adjacent to each other by an interval corresponding to or equal to an interval between the pixels.

The display devices 10_1 to 10_4 may have the same size and may be arranged in a lattice shape, but the disclosure is not limited thereto. Similarly to the display panels 11 to 16 described with reference to FIG. 14, at least some of the display devices 10_1 to 104 may have different sizes (or different shapes, for example, atypical shapes), and the display devices 10_1 to 104 may be arbitrarily arranged. At least some of the display devices 10_1 to 10_4 may have different resolutions.

In an embodiment, the tiled display device TD may further include a seam SM. The seam SM may include a coupling member, an adhesive member, or the like. The display devices 10_1 to 10_4 may be connected to each other through the coupling member, the adhesive member, or the like of the seam SM. The seam SM may be disposed between the first display device 10_1 and the second display device 102, between the first display device 10_1 and the third display device 103, between the second display device 10_2 and the fourth display device 104, and between the third display device 10_3 and the fourth display device 10_4. However, the disclosure is not limited thereto, and similarly to the embodiment of FIGS. 13 and 14, the seam SM may not exist between the display devices 10_1 to 10_4.

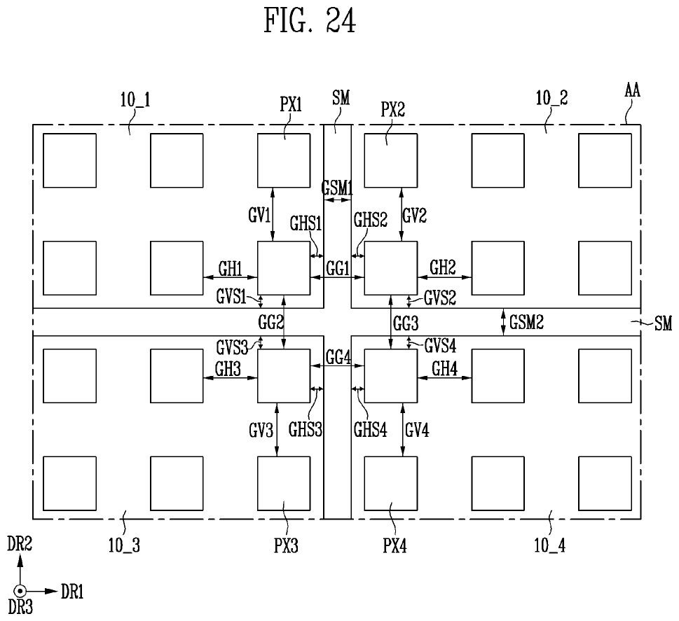

FIG. 24 is a schematic enlarged plan view of area AA of FIG. 23.

Referring to FIG. 24, a first display device 101 may include first pixels PX1 arranged in a matrix form in the first direction DR1 and the second direction DR2 to display an image. The second display device 10_2 may include second pixels PX2 arranged in a matrix form in the first direction DR1 and the second direction DR2 to display an image. The third display device 10_3 may include third pixels PX3 arranged in a matrix form in the first direction DR1 and the second direction DR2 to display an image. The fourth display device 10_4 may include fourth pixels PX4 arranged in a matrix form in the first direction DR1 and the second direction DR2 to display an image. Each of the first to fourth pixels PX1 to PX4 may be the pixel (see, e.g., PX of FIGS. 1 to 3).

A distance (e.g., a minimum distance) between the first pixels PX1 disposed adjacent in the first direction DR1 may be defined as a first horizontal separation distance GH1, and a distance (e.g., a minimum distance) between the second pixels PX2 disposed adjacent in the first direction DR1 may be defined as a second horizontal separation distance GH2. The first horizontal separation distance GH1 and the second horizontal separation distance GH2 may be substantially the same.

The seam SM may be disposed between the first pixel PX1 and the second pixel PX2 disposed adjacent in the first direction DR1. A distance (e.g., a minimum distance) GG1 between the first pixel PX1 and the second pixel PX2 disposed adjacent in the first direction DR1 may be a sum of a distance (e.g., a minimum distance) GHS1 between the first pixel PX1 and the seam SM in the first direction DR1, a distance (e.g., a minimum distance) GHS2 between the second pixel PX2 and the seam SM in the first direction DR1, and a width GSM1 of the seam SM in the first direction DR1.

A distance (e.g., a minimum distance) GG1 between the first pixel PX1 and the second pixel PX2 disposed adjacent in the first direction DR1, the first horizontal separation distance GH1, and the second horizontal separation distance GH2 may be the same. For example, the distance GHS1 between the first pixel PX1 and the seam SM in the first direction DR1 may be less than the first horizontal separation distance GH1, and the distance GHS2 between the second pixel PX2 and the seam SM in the first direction DR1 may be less than the second horizontal separation distance GH2. The width GSM1 of the seam SM in the first direction DR1 may be less than the first horizontal separation distance GH1 or the second horizontal separation distance GH2.

A distance (e.g., a minimum distance) between the third pixels PX3 disposed adjacent in the first direction DR1 may be defined as a third horizontal separation distance GH3, and a distance (e.g., a minimum distance) between the fourth pixels PX4 disposed adjacent in the first direction DR1 may be defined as a fourth horizontal separation distance GH4. The third horizontal separation distance GH3 and the fourth horizontal separation distance GH4 may be substantially the same.

The seam SM may be disposed between the third pixel PX3 and the fourth pixel PX4 disposed adjacent in the first direction DR1. A distance (e.g., a minimum distance) GG4 between the third pixel PX3 and the fourth pixel PX4 disposed adjacent in the first direction DR1 may be a sum of a distance (e.g., a minimum distance) GHS3 between the third pixel PX3 and the seam SM in the first direction DR1, a distance (e.g., a minimum distance) GHS4 between the fourth pixel PX4 and the seam SM in the first direction DR1, and the width GSM1 of the seam SM in the first direction DR1.

The distance GG4 between the third pixel PX3 and the fourth pixel PX4 disposed adjacent in the first direction DR1, the third horizontal separation distance GH3, and the fourth horizontal separation distance GH4 may be substantially the same. For example, the distance GHS3 between the third pixel PX3 and the seam SM in the first direction DR1 may be less than the third horizontal separation distance GH3 and the distance GHS4 between the fourth pixel PX4 and the seam SM in the first direction DR1 may be less than the fourth horizontal separation distance GH4. The width GSM1 of the seam SM in the first direction DR1 may be less than the third horizontal separation distance GH3 or the fourth horizontal separation distance GH4.

A distance (e.g., a minimum distance) between the first pixels PX1 disposed adjacent in the second direction DR2 may be defined as a first vertical separation distance GV1, and a distance (e.g., a minimum distance) between the third pixels PX3 in the second direction DR2 may be defined as a third vertical separation distance GV3. The first vertical separation distance GV1 and the third vertical separation distance GV3 may be substantially the same.

The seam SM may be disposed between the first pixel PX1 and the third pixel PX3 disposed adjacent in the second direction DR2. A distance (e.g., a minimum distance) GG2 between the first pixel PX1 and the third pixel PX3 disposed adjacent in the second direction DR2 may be a sum of a distance (e.g., a minimum distance) GVS1 between the first pixel PX1 and the seam SM in the second direction DR2, a distance (e.g., a minimum distance) GVS3 between the third pixel PX3 and the seam SM in the second direction DR2, and a width GSM2 of the seam SM in the second direction DR2.

The distance GG2 between the first pixel PX1 and the third pixel PX3 disposed adjacent in the second direction DR2, the first vertical separation distance GV1, and the third vertical separation distance GV3 may be substantially the same. For example, the distance GVS1 between the first pixel PX1 and the seam SM in the second direction DR2 may be less than the first vertical separation distance GV1, and the distance GVS3 between the third pixel PX3 and the seam SM in the second direction DR2 may be less than the third vertical separation distance GV3. The width GSM2 of the seam SM in the second direction DR2 may be less than the first vertical separation distance GV1 or the third vertical separation distance GV3.

A distance (e.g., a minimum distance) between the second pixels PX2 disposed adjacent in the second direction DR2 may be defined as a second vertical separation distance GV2, and a distance (e.g., a minimum distance) between the fourth pixels PX4 disposed adjacent in the second direction DR2 may be defined as a fourth vertical separation distance GV4. The second vertical separation distance GV2 and the fourth vertical separation distance GV4 may be substantially the same.

The seam SM may be disposed between the second pixel PX2 and the fourth pixel PX4 disposed adjacent in the second direction DR2. A distance (e.g., a minimum distance) GG3 between the second pixel PX2 and the fourth pixel PX4 disposed adjacent in the second direction DR2 may be a sum of a distance (e.g., a minimum distance) GVS2 between the second pixel PX2 and the seam SM in the second direction DR2, a distance (e.g., a minimum distance) GVS4 between the fourth pixel PX4 and the seam SM in the second direction DR2, and the width GSM2 of the seam SM in the second direction DR2.

The distance GG3 between the second pixel PX2 and the fourth pixel PX4 disposed adjacent in the second direction DR2, the second vertical separation distance GV2, and the fourth vertical separation distance GV4 may be substantially the same. For example, the distance GVS2 between the second pixel PX2 and the seam SM in the second direction DR2 may be less than the second vertical separation distance GV2, and the distance GVS4 between the fourth pixel PX4 and the seam SM in the second direction DR2 may be less than the fourth vertical separation distance GV4. The width GSM2 of the seam SM in the second direction DR2 may be less than the second vertical separation distance GV2 or the fourth vertical separation distance GV4.

Referring to FIG. 24, the distance between the pixels of the display devices disposed adjacent to each other and the distance between the pixels of each of the display devices may be substantially the same so that the seam SM may be not visually recognized between images displayed by the display devices 10_1 to 10_4.

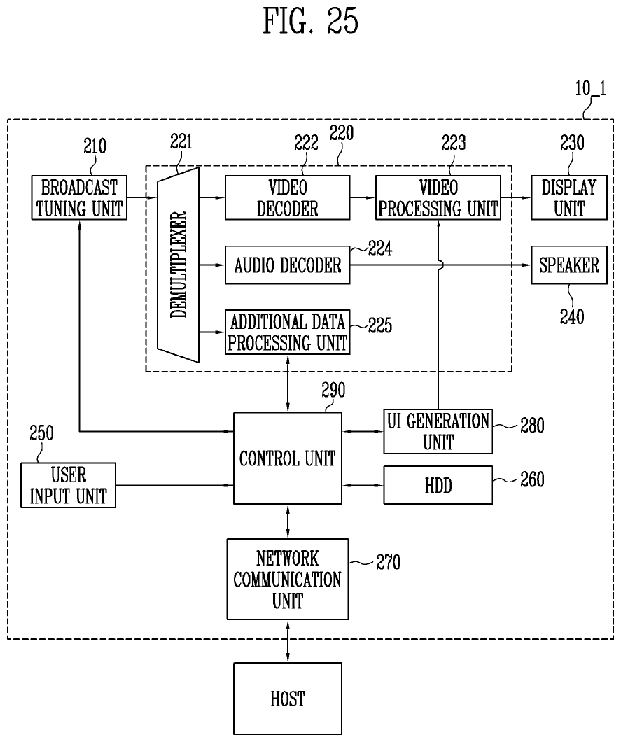

FIG. 25 is a schematic block diagram illustrating a tiled display device according to an embodiment. FIG. 25 illustrates the first display device 10_1 and a host system HOST for convenience of description.

Referring to FIGS. 23 and 25, the tiled display device TD according to an embodiment may include a host system HOST, a broadcast tuning part 210, a signal processing part 220, a display part 230, a speaker 240, a user input part 250, an HDD 260, a network communication part 270, a UI generation part 280, and a control part 290.

The host system HOST may be implemented as one of a television system, a home theater system, a set-top box, a navigation system, a DVD player, a Blu-ray player, a personal computer, a mobile phone system, a tablet, and the like.

A user's instruction may be input to the host system HOST in various formats. For example, an instruction by a user's touch input may be input to the host system HOST. In another embodiment, a user's instruction may be input to the host system HOST by a keyboard input, a button input of a remote controller, or the like.

The host system HOST may receive original video data corresponding to an original image from an outside. The host system HOST may divide the original video data by the number of display devices. For example, the host system HOST may divide the original video data into first video data corresponding to a first image, second video data corresponding to a second image, third video data corresponding to a third image, and fourth video data corresponding to a fourth image, in response to the first display device 10_1, the second display device 10_2, the third display device 103, and the fourth display device 10_4. The host system HOST may transmit the first video data to the first display device 10_1, transmit the second video data to the second display device 10_2, transmit the third video data to the third display device 103, and transmit the fourth video data to the fourth display device 10_4.

The first display device 10_1 may display the first image according to the first video data, the second display device 10_2 may display the second image according to the second video data, the third display device 10_3 may display the third image according to the third video data, and the fourth display device 104 may display the fourth image according to the fourth video data. Accordingly, the user may view the original image in which the first to fourth images displayed on the first to fourth display devices 10_1 to 10_4 are combined.

The first display device 10_1 may include the broadcast tuning part 210, the signal processing part 220, the display part 230, the speaker 240, the user input part 250, the HDD 260, the network communication part 270, the UI generation part 280, and the control part 290.

The broadcast tuning part 210 may tune a channel frequency (e.g., a predetermined or selectable channel frequency) under control of the control part 290 and receive a broadcast signal of a corresponding channel through an antenna. The broadcast tuning part 210 may include a channel detection module (not shown) and an RF demodulation module (not shown).

A broadcast signal demodulated by the broadcast tuning part 210 may be processed by the signal processing part 220 and output to the display part 230 and the speaker 240. The signal processing part 220 may include a demultiplexer 221, a video decoder 222, a video processing part 223, an audio decoder 224, and an additional data processing part 225.

The demultiplexer 221 may divide the demodulated broadcast signal into a video signal, an audio signal, and additional data. The divided video signal, audio signal, and additional data may be restored by the video decoder 222, the audio decoder 224, and the additional data processing part 225, respectively. The video decoder 222, the audio decoder 224, and the additional data processing part 225 may restore as a decoding format corresponding to an encoding format in case that the broadcast signal is transmitted.

A decoded video signal may be converted by the video processing part 223 to fit a vertical frequency, resolution, aspect ratio of an image, and the like corresponding to an output standard of the display part 230, and a decoded audio signal may be output to the speaker 240.

The display part 230 may include a display panel (not shown) on which an image is displayed, and a panel driver (not shown) that controls driving of the display panel.

The user input part 250 may receive a signal transmitted from the host system HOST. The user input part 250 may receive data for selection and input of an instruction related to communication with other display devices by the user as well as data related to selection of a channel transmitted by the host system HOST, and selection and manipulation of a user interface (UI) menu.

The HDD 260 may store various software programs including an OS program, a recorded broadcast program, a moving picture, a photo, and other data, and may be formed of a storage medium such as a hard disk, a nonvolatile memory, or the like.

The network communication part 270 may be for short-range communication with the host system HOST and other display devices, and may be implemented with a communication module including an antenna pattern that implements mobile communication, data communication, Bluetooth, RF, Ethernet, and the like.

The network communication part 270 may transmit and receive a wireless signal with at least one of a base station, an external terminal, and a server on a mobile communication network built according to technical standards or a communication method (for example, global system for mobile communication (GSM), code division multi access (CDMA), code division multi access 2000 (CDMA2000), enhanced voice-data optimized or enhanced voice-data only (EV-DO), wideband CDMA (WCDMA), high speed downlink packet access (HSDPA), high speed uplink packet access (HSUPA), long term evolution (LTE), long term evolution-advanced (LTE-A), 5G, or the like) for mobile communication through an antenna pattern to be described below.

The network communication part 270 may transmit and receive a wireless signal in a communication network according to wireless Internet technologies through the antenna pattern to be described below. The wireless Internet technologies may include, for example, wireless LAN (WLAN), wireless-fidelity (Wi-Fi), wireless fidelity (Wi-Fi) direct, digital living network alliance (DLNA), wireless broadband (WiBro), world interoperability for microwave access (WiMAX), high speed downlink packet access (HSDPA), high speed uplink packet access (HSUPA), long term evolution (LTE), long term evolution-advanced (LTE-A), and the like, and the antenna pattern may transmit and receive data according to at least one wireless Internet technology within a range including Internet technology which are not listed above.

The UI generation part 280 may generate a UI menu for communication with the host system HOST and other display devices, and may be implemented by an algorithm code and an OSD IC. The UI menu for communication with the host system HOST and other display devices may be a menu for designating a counterpart digital TV for communication and selecting a function (e.g., a desired function).

The control part 290 may be in charge of overall control of the first display device 10_1 and be in charge of communication control of the host system HOST and the second to fourth display devices 10_2, 10_3, and 10_4, and a corresponding algorithm code for control may be stored, and the control part 290 may be implemented by a micro controller part (MCU) in which the stored algorithm code is executed.

The control part 290 may control to transmit a corresponding control instruction and data to the host system HOST and the second to fourth display devices 10_2, 10_3, and 10_4 through the network communication part 270 according to an input and selection of the user input part 250. Of course, in case that a control instruction and data (e.g., a predetermined or selectable control instruction and data) are input from the host system HOST and the second to fourth display devices 10_2, 10_3, and 10_4, an operation may be performed according to the corresponding control instruction.

Since a block diagram of the second display device 10_2, a block diagram of the third display device 103, and a block diagram of the fourth display device 10_4 and the block diagram of the first display device 10_1 described in conjunction with FIG. 25 are substantially the same, a description of the block diagram of the second to fourth display device 10_2, 10_3, and 10_4 is omitted.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are the scope of the disclosure.

What is claimed is:

1. A display device comprising:
a substrate including a groove on a lower surface;
a conductive pattern disposed in the groove of the substrate;
a bridge pattern disposed on the substrate and electrically connected to the conductive pattern through a contact hole passing through the substrate;
a first insulating layer disposed on the substrate and covering the bridge pattern;
a transistor disposed on the first insulating layer;
a second insulating layer disposed on the substrate and covering the transistor; and
a light emitting element disposed on the second insulating layer, wherein
the bridge pattern is electrically connected to the transistor or the light emitting element,
a first valley different from the groove is further formed on the lower surface of the substrate, and
the conductive pattern is not disposed in the first valley.

2. The display device according to claim 1, wherein the substrate is a flexible substrate.

3. The display device according to claim 1, wherein in a cross-sectional view, a shape of the first valley and a shape of the groove are different from each other.

4. The display device according to claim 3, wherein, in a cross-sectional view
the groove has a semicircular shape, and
the first valley has a triangular shape.

5. The display device according to claim 1, wherein, in a plan view, the first valley extends in a first direction and is repeatedly arranged in a second direction intersecting the first direction with an interval corresponding to the light emitting element.

6. The display device according to claim 5, wherein, in a plan view, the first valley is arranged in a mesh structure over an entire area of the substrate.

7. The display device according to claim 1, further comprising:
a pixel defining layer disposed on the second insulating layer, wherein
an opening for disposing the light emitting element and a second valley different from the opening are formed in the pixel defining layer, and
the first valley overlaps the second valley in a plan view.

8. The display device according to claim 1, further comprising:
a circuit board disposed under the substrate and electrically connected to the conductive pattern through the groove of the substrate.

9. The display device according to claim 1, wherein
the groove includes a curved surface, and
the conductive pattern includes a curved surface corresponding to the groove.

10. The display device according to claim 9, wherein at least a portion of the groove is defined by a lower surface of the conductive pattern.

11. The display device according to claim 1, wherein
the light emitting element is included in a plurality of sub-pixels, and
the groove is repeatedly arranged with an interval corresponding to at least one of the plurality of sub-pixels in a first direction.

12. The display device according to claim 11, wherein
the groove has a size corresponding to the plurality of sub-pixels, and
a plurality of conductive patterns are disposed in the groove.

13. A method of manufacturing a display device, the method comprising:
forming a first mold pattern on a carrier substrate;
forming a conductive pattern on the first mold pattern;
forming a base layer on the carrier substrate to cover the first mold pattern and the conductive pattern;
forming a transistor on the base layer;
separating the carrier substrate and the first mold pattern from the base layer; and
mounting a light emitting element on the base layer, wherein a groove corresponding to the first mold pattern is formed on a lower surface of the base layer.

14. The method according to claim 13, wherein
the forming of the first mold pattern comprises:
forming a sacrificial layer on the carrier substrate; and
stamping the sacrificial layer using a mold including a second groove corresponding to the first mold pattern, and
the sacrificial layer includes silica sol-gel (Si sol-gel) or a polymeric organic material.

15. The method according to claim 13, wherein
the forming of the first mold pattern further comprises forming a second mold pattern together with the first mold pattern,
in a cross-sectional view, a shape of the second mold pattern and a shape of the first mold pattern are different from each other, and
a first valley corresponding to the second mold pattern is formed on a lower surface of the base layer.

16. The method according to claim 15, wherein
the forming of the transistor comprises forming a pixel defining layer on the base layer,
an opening for disposing the light emitting element and a second valley different from the opening are formed in the pixel defining layer, and
the first valley overlaps the second valley in a plan view.

17. A tiled display device comprising:
a plurality of display devices each including pixels, wherein
the plurality of display devices are disposed adjacent to each other by an interval corresponding to an interval between the pixels,
at least one of the plurality of display devices comprises:
a substrate including a groove on a lower surface;
a conductive pattern disposed in the groove of the substrate;
a bridge pattern disposed on the substrate and electrically connected to the conductive pattern through a contact hole passing through the substrate;
a first insulating layer disposed on the substrate and covering the bridge pattern;
a transistor disposed on the first insulating layer;
a second insulating layer disposed on the substrate and covering the transistor; and
a light emitting element disposed on the second insulating layer,
the bridge pattern is electrically connected to the transistor or the light emitting element, and
a first valley different from the groove is further formed on the lower surface of the substrate.

18. The tiled display device according to claim 17, wherein at least some of the plurality of display devices have different sizes or different shapes.

19. The tiled display device according to claim 17, wherein at least some of the plurality of display devices have different resolutions.

20. The tiled display device according to claim 17, wherein the substrate is a flexible substrate.
